(19) United States
(12) Patent Application Publication
(10) Pub. No.: US 2013/0056749 A1
(43) Pub. Date: Mar. 7, 2013

(54) BROAD-AREA LIGHTING SYSTEMS

(71) Applicants: Michael Tischler, Scottsdale, AZ (US); Philippe Schick, Vancover (CA); Calvin Wade Sheen, Derry, NH (US)

(72) Inventors: Michael Tischler, Scottsdale, AZ (US); Philippe Schick, Vancover (CA); Calvin Wade Sheen, Derry, NH (US)

(21) Appl. No.: 13/604,880

(22) Filed: Sep. 6, 2012

Related U.S. Application Data
(60) Provisional application No. 61/531,676, filed on Sep. 7, 2011.
(60) Provisional application No. 61/589,908, filed on Jan. 24, 2012.

(51) Int. Cl. H01L 33/60; H01L 33/44

(52) U.S. Cl. 257/76; 257/88; 257/E33.023; 257/E33.061; 257/E33.072

(57) ABSTRACT

In accordance with certain embodiments, illumination systems are formed by aligning light-emitting elements with optical elements and/or disposing light-conversion materials on the light-emitting elements, as well as by providing electrical connectivity to the light-emitting elements

### RELATED APPLICATIONS

This application claims the benefit of and priority to U.S. Provisional Patent Application No. 61/531,676, filed Sep. 7, 2011, and U.S. Provisional Patent Application No. 61/589,908, filed Jan. 24, 2012, the entire disclosure of each of which is hereby incorporated herein by reference.

### FIELD OF THE INVENTION

In various embodiments, the present invention generally relates to electronic devices, and more specifically to array-based electronic devices.

### BACKGROUND

Light sources such as light-emitting diodes (LEDs) are an attractive alternative to incandescent and fluorescent light bulbs in illumination devices due to their higher efficiency, smaller form factor, longer lifetime, and enhanced mechanical robustness. However, the high cost of LEDs and associated heat-sinking and thermal-management systems have limited the widespread utilization of LEDs, particularly in broad-area general lighting applications.

The high cost of LED-based lighting systems has several contributors. LEDs are typically encased in a package, and multiple packaged LEDs are used in each lighting system to achieve the desired light intensity. In order to reduce costs, LED manufacturers have developed high-power LEDs that emit relatively higher light intensities by operating at higher currents. While reducing the package count, these LEDs require higher-cost packages to accommodate the higher current levels and to manage the significantly higher resulting heat levels. The higher heat loads and currents, in turn, typically require more expensive thermal-management and heat-sinking systems —for example, thermal slugs in the package, ceramic or metal submounts, large metal or ceramic heat sinks, metal core printed circuit boards and the like—which also add to the cost (as well as to the size) of the system. Higher operating temperatures may also lead to shorter lifetimes and reduced reliability. Finally, LED efficacy typically decreases with increasing drive current, so operation of LEDs at higher currents generally results in a reduction in efficacy when compared to lower-current operation.

A further problem associated with using a relatively small number of high-power LEDs in broad-area lighting, for example to replace fluorescent lighting systems, is that the light must be expanded from the relatively small area of the die (on the order of 1 mm²) to emit over a relatively large area (on the order of 1 ft² or larger). Such expansion often results in decreased efficiency, reduced performance, and increased cost. For example, one possible approach is the use of an edge-lit panel that incorporates features in the panel that redirect or scatter light. However, such edge-lit structures typically have a relatively lower efficiency. In addition, it is difficult to achieve uniform light intensity over the entire emitting area, with the intensity generally being higher at the edge(s) near the light sources. Another problem is that the emission pattern from such devices is typically Lambertian, resulting in poor utilization of light and relatively high glare.

An alternate approach to producing broad-area lighting is to use a large array of small LEDs positioned over the desired emitting area. This minimizes or eliminates the cost and efficiency losses associated with optics required to spread out light from a small number of high-power LEDs. However, this approach typically involves a relatively complex fabrication process that in some cases may require highly customized chips, factors resulting in potentially reduced yields and higher costs. For example, this approach may involve (i) non-standard dies having a “dipole” geometry and a self-assembled alignment process that may be difficult to achieve with very high yield, or (ii) use of LED dies with top and bottom contacts (i.e., not the standard form of GaN-based LEDs used for general illumination). Top and bottom contacted GaN-based LEDs may be fabricated, but the increased processing cost, in part related to removal of the sapphire substrate, has traditionally only been justified for expensive large-area high-power LEDs. Finally, arrays of LEDs by themselves may produce an undesirable substantially Lambertian light distribution pattern.

A further problem with any LED-based system for general illumination is that integration with a light-conversion material (such as a phosphor) for the production of white light is often difficult, particularly in terms of uniformity and reproducibility. LEDs generally emit in a relatively narrow wavelength range, for example on the order of about 20-100 nm. When broader spectra (for example “white” light) or colors different from that of the LED are desired, the LED may be combined with one or more light-conversion materials. A phosphor-coated LED generates white light by combining the short-wavelength radiant flux emitted by the semiconductor LED with long-wavelength radiant flux emitted by one or more phosphors. The phosphors are typically composed of phosphorescent particles such as Y₃Al₅O₁₂:Ce³⁺ (cerium-activated yttrium-aluminum-garnet, or YAG:Ce) embedded in a transparent binder such as optical epoxy or silicone.

As described in, e.g., Zhu, Y., N. Narendran, and Y. Gu. 2006. “Investigation of the Optical Properties of YAG:Ce Phosphor,” Sixth International Conference on Solid

State Lighting, Proc. SPIE Vol. 6337, 63370S-1 (“the Zhu reference”), the phosphor layer absorbs a portion of the incident short-wavelength radiant flux and re-emits long-wavelength radiant flux. In an exemplary YAG:Ce phosphor, as depicted by the graph in FIG. 1, a blue LED typically has a peak wavelength between about 440 nm and about 470 nm, corresponding to the peak of the phosphor-excitation spectrum, while the phosphor emission has a broadband spectrum with a peak at approximately 560 nm. Combining the blue LED emission with the yellow phosphor emission yields visible white light with a specific chromaticity (color) that depends on the ratio of blue to yellow light.

The geometry of the phosphor relative to the LED generally has a very strong impact on the uniformity of the light characteristics. For example, the LED may emit from both the surface and the sides of the LED, producing non-uniform color if the phosphor composition is not uniform over the sides and top of the LED. To combat this problem, the LED may be placed in a reflecting cavity covered by a wavelength-converting material (e.g., a ceramic), such that all of the light from the LED exits the cavity through the converter. However, such wavelength converters may be difficult to manufacture and brittle in thin-film form. Furthermore, they may be expensive to integrate in arrays of small LEDs.

Another issue with using phosphors to convert the short-wavelength radiant flux to long-wavelength radiant flux is isotropic emission from phosphors. Consequently, approximately half of the long-wavelength flux is emitted back towards the LED. As reported by the Zhu reference, 47% of the measured flux emitted by a YAG:Ce phosphor layer was directed back towards the blue light source, where a portion of it may be absorbed, resulting in reduced efficiency.

In order to be commercially viable, the manufacture of large arrays of LEDs desirably includes a cost-effective approach to position and form electrical connections to each LED in the array. Conventional wire bonding is too expensive when arrays number thousands of LEDs or more. As discussed above, a variety of self-assembly techniques for such arrays have been attempted, but these tend to be plagued by incomplete assembly, leading to inhomogeneous light distribution and low light output and efficiency.

Conductive adhesives are another approach that may be used to attach and electrically connect LEDs. However, as the LED die size shrinks, it becomes increasingly difficult to prevent short-circuiting of the die by the conductive adhesive. One recent advance facilitating the connectivity of LEDs to a variety of substrates is anisotropically conductive adhesive (ACA), which enables electrical interconnection in one direction (e.g., vertically between a device contact and a substrate contact), but prevents it in other directions (e.g., horizontally between contacts on a device or between contracts on a substrate). There are a number of different modes of operation of ACAs, including with and without pressure activation. As known in the art, a pressure-activated ACA typically includes an adhesive base, e.g., an adhesive or epoxy material, containing “particles” (e.g., spheres) of a conductive material or of an insulating material coated with a conductive material (such as metal) or a conductive material coated with an insulating material. FIG. 2 depicts a conventional use of pressure-activated ACA to connect an electronic device to a substrate. As shown, an electronic device 230 having multiple contacts 240 has been adhered and electrically connected to conductive traces 220 formed over substrate 210 via use of an ACA 260. ACA 260 features an adhesive base 264 containing a dispersion of particles 262 that are at least partially conductive.

ACAs also have the advantage of applicability to relatively small contacts on an LED; in contrast, wire bonding typically requires a contact size on the order of 80 μm in diameter. The use of smaller contacts permits an increase in the emitting area relative to the total chip area, permitting a reduction in the overall chip size and a reduction in chip cost. Another advantage of using relatively smaller chips is that yield loss caused by “killer” particles or other defects (i.e., those whose presence in the area of the chip render it inoperative) is generally proportional to chip area, and thus smaller chips may have a higher yield and thus lower overall cost.

Referring again to FIG. 2, state-of-the-art pressure-activated ACAs generally require provision of “stud bumps” or other metallic projections 225 on the surface to which the LED is to be bonded or on the LED bond pads in order to achieve the anisotropic electrical conductivity and reliable adhesion. More recently, an approach to the use of ACA without stud bumps has been disclosed in U.S. Patent Application Serial No. 13/171,973, filed Jun. 29, 2011, the entire disclosure of which is incorporated by reference herein.

As discussed above, while arrays of LEDs may be used to produce uniform illumination across a large area, they do not, by themselves, necessarily produce a desired light-distribution pattern (e.g., one that provides desired illumination levels with low glare). One method to address this deficiency is to couple the array of light emitters with an array of optical elements designed to produce a specific light-distribution pattern. Such an array of optical elements may include arrays of refractive optical elements, Fresnel elements, or the like. These may be fabricated in a variety of optical materials such as acrylic or polycarbonate by, e.g., molding, casting, or embossing. Alignment of the optical elements with the LEDs may be critical in order to achieve the desired light-distribution pattern. This is particularly the case for an array of LEDs, where the overall light-distribution pattern is a superposition of the light emitted by each LED through each optical element and where different thermal budgets and/or thermal coefficients of expansion of different components of the system may generate misalignment during the fabrication process or in the field.

In view of the foregoing, a need exists for systems and procedures enabling the uniform and low cost integration of arrays of low cost light sources (such as LEDs), phosphors, and optical elements, as well as low cost, reliable LED-based lighting systems based on such systems and processes.

### SUMMARY

In accordance with certain embodiments, illumination devices (which are preferably planar) feature a plurality of light-emitting elements electrically connected in series, parallel, or in series/parallel fashion. The light-emitting elements may have light-conversion materials such as phosphors disposed over and/or around them, and may also be aligned to optical elements (e.g., lenses) disposed on or forming portions of an overlying optical substrate. In preferred embodiments, the integration of the light-conversion material and/or the optical elements with the light-emitting elements is repeatably and uniformly performed in parallel. For example, a substrate having the light-emitting elements disposed thereon (i.e., a “lightsheet”) may be directly bonded to the optical substrate, the light-emitting elements having been positioned for alignment with the optical elements of the optical substrate. Furthermore, low-cost methods such as screen printing may be utilized to form electrical conductors (e.g., “jumpers” or other electrical traces or connections) over the light-emitting elements or on the lightsheet to facilitate production of illumination devices incorporating arrays of tens, hundreds, or even thousands of light-emitting elements.

As utilized herein, an “optical substrate” is a material for receiving, manipulating, and/or transmitting light. An optical substrate may include or consist essentially of, e.g., a transparent or translucent sheet or plate, a waveguide and/or one or more (even an array of) optical elements such as lenses. For example, optical elements may include or consist essentially of refractive optics, reflective optics, Fresnel optics, total internal reflection optics, and the like. The optical substrate may include features or additional components or materials to scatter, reflect, or absorb light or a portion of light in the optical substrate, and it may confine light by total internal reflection prior to its emission from the optical substrate.

In an aspect, embodiments of the invention feature a method of forming an illumination system that includes or consists essentially of reversibly attaching a light-emitting element to a first substrate, mating (e.g., bonding) the first substrate to a second substrate to transfer the light-emitting element to the second substrate, removing the first substrate from the second substrate, and forming at least two conductors over the light-emitting element and the second substrate to thereby facilitate electrical connectivity to the light-emitting element.

Embodiments of the invention may feature one or more of the following in any of a variety of combinations. The light-emitting element may have at least two contacts disposed on a first side, and the first side of the light-emitting element may be reversibly attached to the first substrate. The first substrate may be mated to the second substrate with an adhesive material. The adhesive material may include or consist essentially of a releasable adhesive, and removing the first substrate from the second substrate may include or consist essentially of releasing the releasable adhesive (e.g., via exposure to heat and/or radiation). The second substrate may include a light-conversion material. The light-conversion material may be disposed on the second substrate, and the light-emitting element may be transferred to the second substrate on the light-conversion material. The second substrate may include a well therewithin. The light-conversion material may be disposed within and at least partially filling the well in the second substrate, and the light-emitting element may be disposed at least partially within the well after being transferred to the second substrate. The light-conversion material may include or consist essentially of a phosphor and a binder. The phosphor may include or consist essentially of lutetium aluminum garnet, yttrium aluminum garnet, a nitride-based phosphor, or a silicate-based phosphor. The binder may include or consist essentially of silicone, polydimethylsiloxane (PDMS), or epoxy. The light-conversion material may be cured. The conductors may be at least partially reflective to a wavelength of light emitted by the light-emitting element and/or a wavelength of light emitted by the light-conversion material. The second substrate may be substantially transparent to a wavelength of light emitted by the light-emitting element and/or a wavelength of light emitted by the light-conversion material. The light-conversion material may be disposed on a surface of the second substrate opposite the surface on which the light-emitting element is disposed, and the light-conversion material may be substantially aligned with the light-emitting element.

The light-emitting element may have two contacts disposed on a single side thereof. The contacts may be substantially coplanar with a surface of the second substrate after the light-emitting element is transferred thereto. Each of the two conductors may be formed over and in electrical contact with one of the contacts, and the conductors may be electrically isolated from each other after formation. A barrier may be formed between the contacts of the light-emitting element prior to formation of the conductors, and the barrier may prevent electrical contact between the conductors during formation thereof (e.g., by printing). The second substrate may include electrical traces thereon prior to being mated (e.g., bonded) to the first substrate, the light-emitting element may be transferred to the second substrate between two of the electrical traces, and each of the conductors may electrically connect a contact with an electrical trace. The light-emitting element may be electrically coupled to the electrical traces with a conductive adhesive (e.g., an anisotropic conductive adhesive). Each of the conductors may directly connect a contact of the light-emitting device to a contact of a different light-emitting element disposed on the second substrate.

The second substrate may include an optical element associated with the light-emitting element. The optical element may be disposed on a surface of the second substrate opposite the surface on the second substrate on which the light-emitting element is disposed. The second substrate may include a well aligned with the optical element.

The conductors may be formed by printing. The light-emitting element may include or consist essentially of a light-emitting diode. The light-emitting diode may include or consist essentially of one or more semiconductor materials selected from the group consisting of silicon, InAs, AlAs, GaAs, InP, AlP, GaP, InSb, GaSb, AlSb, GaN, AlN, InN, and mixtures and alloys thereof. The light-emitting element may have at least two contacts, and, prior to reversibly attaching the light-emitting element to the first substrate, the light-emitting element may be partially surrounded with a light-conversion material such that two contacts of the light-emitting element are not fully covered by light-conversion material.

In another aspect, embodiments of the invention feature a method of forming an illumination system. A light-conversion material is provided within each of a plurality of wells within an optical substrate comprising a plurality of optical elements. A lightsheet comprising a substrate, a plurality of electrical traces disposed on the substrate, and a plurality of light-emitting elements electrically coupled to the electrical traces is provided. The lightsheet is bonded to the optical substrate such that at least one light-emitting element is disposed within each well in the optical substrate.

Embodiments of the invention may feature one or more of the following in any of a variety of combinations. Providing the light-conversion material within the wells may include or consist essentially of dispersing the light-conversion material in liquid or gel form. Providing the light-conversion material within the wells may include or consist essentially of fitting a pre-shaped solid portion of the light-conversion material within each well. After bonding the lightsheet to the optical substrate, each well may be substantially filled by at least one light-emitting element and light-conversion material. During the bonding of the lightsheet and the optical substrate, a portion of the light-conversion material may flow from a well and adhere the lightsheet to the optical substrate. Each light-emitting element may be electrically coupled to the electrical traces with a conductive adhesive (e.g., an anisotropic conductive adhesive).

In yet another aspect, embodiments of the invention feature a method of forming an illumination system. Each of a plurality of bare-die light-emitting elements is partially surrounded with a light-conversion material such that two contacts of each light-emitting element are not fully covered by light-conversion material. Each of the light-emitting elements is inserted into a well in an optical substrate. Each well has an interior-surface shape complementary to the shape of the outer surface of the light-conversion material on the light-emitting element. Electrical traces are formed over each light-emitting element and the optical substrate to thereby facilitate electrical connectivity to the light-emitting elements.

Embodiments of the invention may feature one or more of the following in any of a variety of combinations. Each well in the optical substrate may be aligned with an optical element disposed on the optical substrate. The two contacts of each light-emitting element may be substantially coplanar with a surface of the optical substrate after the light-emitting elements have been inserted into wells. The electrical traces may be formed by printing. Each light-emitting element may be electrically coupled to the electrical traces with a conductive adhesive (e.g., an anisotropic conductive adhesive). A transparent material may be disposed between the interior surface of a well and the outer surface of the light-conversion material on the light-emitting element inserted into the ell. The transparent material may have an index of refraction of at least 1.35.

In a further aspect, embodiments of the invention feature a method of forming an illumination system. A plurality of light-emitting elements are attached to an optical substrate. Each light-emitting element is substantially aligned with an optical element on the optical substrate, electrically connected to at least two electrical traces on the optical substrate, and at least partially surrounded by a light-conversion material. A support substrate is bonded to the optical substrate such that each light-emitting element is disposed within a cavity in the support substrate. The inner surface of each cavity is reflective so as to direct light emitted by the light-emitting element therewithin toward the optical element substantially aligned with the light-emitting element.

Embodiments of the invention may feature one or more of the following in any of a variety of combinations. Each cavity may be substantially parabolic, and the light-emitting element disposed therewithin may be disposed at a focal point thereof. A discrete (i.e., separate) portion of the light-conversion material may be disposed over each light-emitting element after the light-emitting elements are attached to the optical substrate. The inner surface of each cavity may be reflective to a wavelength of light emitted by the light-conversion material. Each light-emitting element may be electrically coupled to the at least two electrical traces with a conductive adhesive (e.g., an anisotropic conductive adhesive).

In yet a further aspect, embodiments of the invention feature a light-emitting device including or consisting essentially of an optical substrate and a plurality of light-emitting elements. The optical substrate includes a plurality of cavities in a first surface thereof and a plurality of electrical traces disposed on the first surface thereof. Each light-emitting element is at least partially inserted into one of the cavities in the optical substrate, electrically connected to at least two electrical traces on the optical substrate, and at least partially surrounded by a light-conversion material. A plurality of optical elements may be disposed on a second surface of the optical substrate opposite the first surface. Each optical element may be substantially aligned with a cavity in the first surface.

In another aspect, embodiments of the invention feature a light-emitting device including or consisting essentially of an optical substrate, a plurality of electrical traces disposed on a first surface of the optical substrate, a plurality of light-emitting elements disposed over the first surface of the optical substrate, and a reflective surface disposed over each light-emitting element. Each light-emitting element is electrically connected to at least two electrical traces on the first surface of the optical substrate and at least partially surrounded by a light-conversion material. The light-conversion material may be disposed on the light-emitting element and/or on the reflective surface. The reflective surface may have a substantially parabolic shape, and the light-emitting element thereunder may be disposed at a focal point thereof. A plurality of optical elements may be disposed on a second surface of the optical substrate opposite the first surface. Each optical element may be substantially aligned with a light-emitting element.

These and other objects, along with advantages and features of the invention, will become more apparent through reference to the following description, the accompanying drawings, and the claims. Furthermore, it is to be understood that the features of the various embodiments described herein are not mutually exclusive and can exist in various combinations and permutations. As used herein, the term “substantially” means ±10%, and in some embodiments, ±5%. The term “consists essentially of” means excluding other materials that contribute to function, unless otherwise defined herein. Nonetheless, such other materials may be present, collectively or individually, in trace amounts.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 is a graph illustrating emission spectra of an LED and a phosphor material integrated therewith;

FIG. 2 is a schematic illustration of a semiconductor die bonded to a substrate having stud bumps via an ACA;

FIG. 3A is a schematic plan view of a lighting system featuring multiple light-emitting elements adhered to a common substrate in accordance with various embodiments of the invention;

FIG. 3B is a schematic cross-section of one of the light-emitting elements of FIG. 3A;

FIG. 3C is a schematic plan view of two light-emitting elements disposed between common electrical contacts in accordance with various embodiments of the invention;

FIGS. 4A and 4B are schematic plan views of lighting devices having two different layouts of conductive traces, in accordance with various embodiments of the invention;

FIGS. 5A and 5B are schematic illustrations of a semiconductor die in different stages of processing, in accordance with various embodiments of the invention;

FIG. 5C is a schematic illustration of a semiconductor die, in accordance with an embodiment of the invention;

FIGS. 6A and 6B are schematic cross-sections of lighting devices incorporating phosphors and reflective materials in accordance with various embodiments of the invention;

FIGS. 7-10 are schematic cross-sections of light-emitting elements integrated with phosphor materials in accordance with various embodiments of the invention;

FIG. 11 is a schematic illustration of a phosphor cap utilized in various embodiments of the invention;

FIG. 12 is a schematic cross-section of phosphor regions integrated with an optical substrate in accordance with various embodiments of the invention;

FIG. 13 is a schematic cross-section of a lighting device featuring bonded light emitters disposed within phosphor-containing wells in an optical substrate in accordance with various embodiments of the invention;

FIG. 14 is a schematic cross-section of an optical substrate having wells disposed therein in accordance with various embodiments of the invention;

FIG. 15 is a schematic plan view of an optical substrate depicting wells of different shapes in accordance with various embodiments of the invention;

FIG. 16 depicts the optical substrate of FIG. 14 with phosphor disposed in the wells thereof, in accordance with various embodiments of the invention;

FIG. 17 is a schematic cross-section of a substrate with electrical traces and semiconductor dies disposed thereon in accordance with various embodiments of the invention;

FIG. 18 is a schematic plan view of a semiconductor die electrically connected to reflective electrical traces in accordance with various embodiments of the invention;

FIGS. 19-21 are schematic cross-sections of lighting devices incorporating phosphor materials and/or optical elements in accordance with various embodiments of the invention;

FIGS. 22-24 are schematic cross-sections of process steps for disposing light-emitting elements within phosphor-containing wells in an optical substrate in accordance with various embodiments of the invention;

FIG. 25 is a schematic plan view of light-emitting elements within phosphor-containing wells in an optical substrate in accordance with various embodiments of the invention;

FIGS. 26A and 26B are, respectively, a schematic plan view and a schematic cross-section of electrical contacts formed over light-emitting elements within phosphor-containing wells in an optical substrate in accordance with various embodiments of the invention;

FIGS. 27A and 27B are, respectively, a schematic plan view and a schematic cross-section of a barrier formed between contacts of a semiconductor die in accordance with various embodiments of the invention;

FIGS. 28A and 28B are, respectively, a schematic cross-section and a schematic plan view of a screen-printing process performed on the structure of FIGS. 27A and 27B in accordance with various embodiments of the invention;

FIG. 29 is a schematic cross-section of a semiconductor die having electrical contacts screen-printed thereon in accordance with various embodiments of the invention;

FIG. 30 is a schematic plan view of a semiconductor die with a barrier formed between contacts thereof in accordance with various embodiments of the invention;

FIG. 31 is a schematic plan view of an array of semiconductor dies prior to electrical interconnection in accordance with various embodiments of the invention;

FIG. 32 depicts the array of FIG. 31 after electrical interconnection in accordance with various embodiments of the invention;

FIG. 33 is a schematic cross-section of a lighting device incorporating a light-emitting element disposed on the opposite side of a transparent substrate from a well containing phosphor material in accordance with various embodiments of the invention;

FIGS. 34 and 35 depict the structures of FIGS. 13 and 26B but with optical substrates replaced by substrates without optical elements in accordance with various embodiments of the invention;

FIG. 36 is a schematic cross-section of a lighting device featuring a light-emitting element disposed within a well of phosphor in accordance with various embodiments of the invention;

FIGS. 37A and 37B are, respectively, a schematic cross-section and a schematic plan view of semiconductor dies disposed within wells formed on a temporary substrate in accordance with various embodiments of the invention;

FIG. 38 depicts the structure of FIG. 37A after dispersal of phosphor within the die-containing wells and removal of the temporary substrate in accordance with various embodiments of the invention;

FIG. 39 is a schematic cross-section of a lighting device featuring multiple light-emitting elements disposed in a single well of phosphor material in accordance with various embodiments of the invention;

FIGS. 40A, 40B, and 40C are circuit diagrams of different interconnection schemes for devices in accordance with various embodiments of the invention;

FIG. 41 is a schematic cross-section of a stand-alone phosphor-coated light-emitting element utilized in accordance with various embodiments of the invention; and

FIGS. 42 and 43 are schematic cross-sections of the fabrication of a lighting device utilizing the element of FIG. 41 in accordance with various embodiments of the invention.

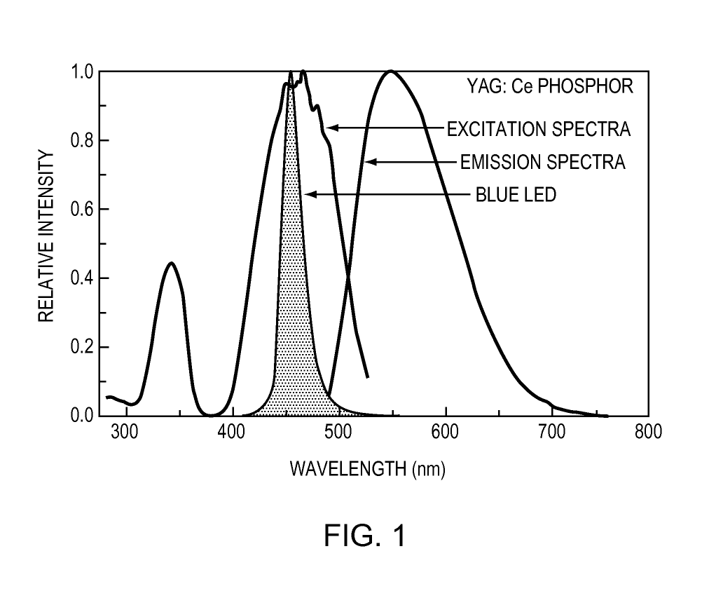

### DETAILED DESCRIPTION

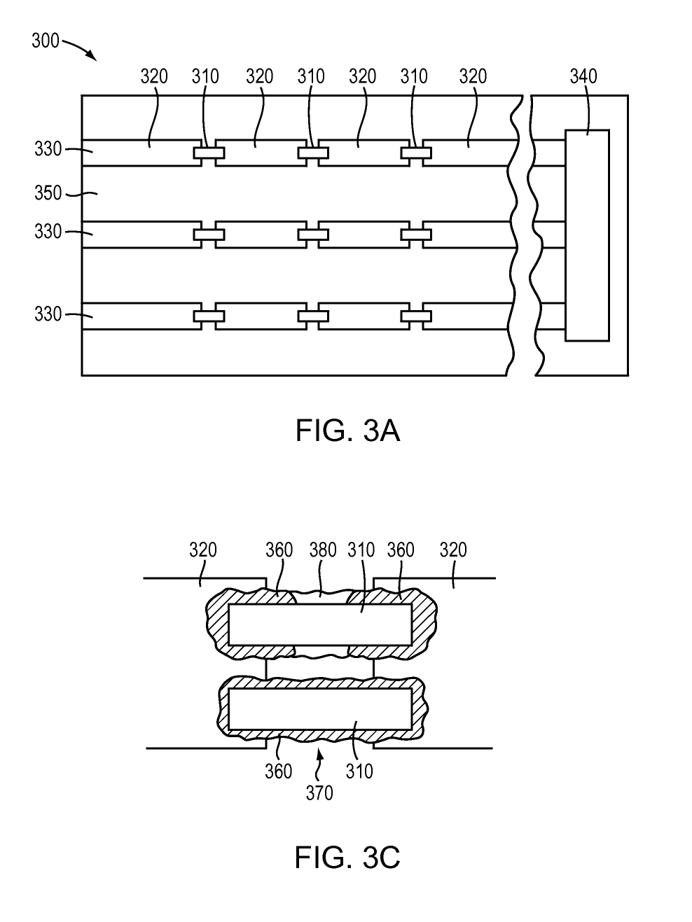

FIG. 3A depicts an electronic device 300 in accordance with embodiments of the present invention featuring an array of semiconductor dies 310 electrically coupled between conductive traces 320. In one embodiment, the semiconductor dies 310 are electrically coupled using conductive adhesive, e.g., an isotropically conductive adhesive and/or an ACA. In one embodiment the semiconductor dies 310 are electrically coupled using a solder or a low-temperature solder. As shown, electronic device 300 includes three serially-connected strings 330 of semiconductor dies 310. Electronic device 300 also includes circuitry 340 electrically connected to one or more of the strings 330. The circuitry 340 may include or consist essentially of portions or substantially all of the drive circuitry, sensors, control circuitry, dimming circuitry, and or power-supply circuitry or the like, and may also be adhered (e.g., via an adhesive) or otherwise attached to a substrate 350. In one embodiment, the power supply and driver are distributed, e.g., the device 300 may have a centralized power supply and all or a portion of the drive circuitry distributed in different locations. Circuitry 340 may even be disposed on a circuit board (e.g., a printed circuit board) that itself may be mechanically and/or electrically attached to substrate 350. In other embodiments, circuitry 340 is separate from substrate 350. While FIG. 3A depicts the semiconductor die 310 serially connected in strings 330, and strings 330 connected or connectable in parallel, other die-interconnection schemes are possible and within the scope of embodiments of the invention. ACAs may be utilized with or without stud bumps, and embodiments of the present invention are not limited by the particular mode of operation of the ACA. For example, the ACA may utilize a magnetic field rather than pressure (e.g., the ZTACH ACA available from SunRay Scientific of Mt. Laurel, N.J., for which a magnetic field is applied during curing in order to align magnetic conductive particles to form electrically conductive “columns” in the desired conduction direction). Furthermore, various embodiments utilize one or more other electrically conductive adhesives, e.g., isotropically conductive adhesives, in addition to or instead of one or more ACAs.

Electronic device 300 may be formed in a roll-to-roll process, in which a sheet of the substrate material travels through different processing stations. Such roll-to-roll processing may, for example, include the formation of conductive traces 320, dispensing of the adhesive 360 (see FIG. 3B), and the placement of semiconductor dies 310, as well as for the bonding of any additional substrates and/or formation of one or more phosphor materials and optical elements (as detailed below). In addition, electronic device 300 may also include other passive and/or active electronic devices attached to substrate 350, including, e.g., sensors, antennas, resistors, inductors, capacitors, thin-film batteries, transistors and/or integrated circuits. Such other passive and/or active electronic devices may be electrically coupled to conductive traces 320 or semiconductor dies 300 with adhesive 360 or by other approaches.

FIG. 3B shows a schematic of the connection of semiconductor die 310 to conductive traces 320 using an adhesive 360 and includes or consists essentially of an ACA. In other embodiments, adhesive 360 may include or consist essentially of other types of adhesives, in which case the location or positioning of adhesive 360 may be different than that shown schematically in FIG. 3B. In one embodiment, one or more of the semiconductor dies 310 includes a light-emitting element and at least two contacts 312 and 314 that are connected to adjacent portions of conductive traces 320. In one embodiment, adhesive 360 includes or consists essentially of an ACA. One or more of the semiconductor dies 310 may be a light emitting element having contacts 312 and 314 that provide electrical contact to the p- and n-side of the light-emitting element respectively.

As utilized herein, the term “light-emitting element” (LEE) refers to any device that emits electromagnetic radiation within a wavelength regime of interest, for example, visible, infrared or ultraviolet regime, when activated, by applying a potential difference across the device or passing a current through the device. Examples of light-emitting elements include solid-state, organic, polymer, phosphor-coated or high-flux LEDs, laser diodes or other similar devices as would be readily understood. The emitted radiation of an LEE may be visible, such as red, blue or green, or invisible, such as infrared or ultraviolet. An LEE may produce radiation of a spread of wavelengths. An LEE may feature a phosphorescent or fluorescent material for converting a portion of its emissions from one set of wavelengths to another. An LEE may include multiple LEEs, each emitting essentially the same or different wavelengths. In some embodiments, an LEE is an LED that may feature a reflector over all or a portion of its surface upon which electrical contacts (e.g., contacts 312, 314) are positioned. The reflector may also be formed over all or a portion of the contacts themselves. In some embodiments, the contacts are themselves reflective. Herein “reflective” is defined as having a reflectivity greater than 65% for a wavelength of light emitted by the LEE on which the contacts are disposed. In some embodiments, an LEE may include or consist essentially of a packaged LED, i.e., a bare LED die encased or partially encased in a package. In some embodiments, the packaged LED may also include a light-conversion material. In some embodiments, the light from the LEE may include or consist essentially of light emitted only by the light-conversion material, while in other embodiments, the light from the LEE may include or consist essentially of a combination of light emitted from the bare LED die and from the light-conversion material. In some embodiments, the light from the LEE may include or consist essentially of light emitted only by a bare LED die.

As shown in FIG. 3A, the lighting system 300 may feature multiple strings, each string including or consisting essentially of a combination of one or more LEEs electrically connected in series, in parallel, or in a series-parallel combination with optional fuses, antifuses, current-limiting resistors, zener diodes, transistors, and other electronic components to protect the LEEs from electrical fault conditions and limit or control the current flow through individual LEEs or electrically-connected combinations thereof. In general, such combinations feature an electrical string that has at least two electrical connections for the application of DC or AC power. A string may also include a combination of one or more LEEs electrically connected in series, in parallel, or in a series-parallel combination of LEEs with or without additional electronic components. FIG. 3A shows three strings of LEEs, each string having three LEEs in series.

As shown in FIG. 3C, two or more semiconductor dies 310 may be connected in parallel to the same conductive traces 320 (i.e., within the same gap 370 between conductive traces 320), thus providing enhanced functionality and/or redundancy in the event of failure of a single semiconductor die 310. In a preferred embodiment, each of the semiconductor dies 310 adhered across the same gap 370 is configured not only to operate in parallel with the others (e.g., at substantially the same drive current), but also to operate without overheating or damage at a drive current corresponding to the cumulative drive current operating all of the semiconductor dies 310 disposed within a single gap. Thus, in the event of failure of one or more of the semiconductor dies 310 adhered across the gap 370, the remaining one or more semiconductor dies 310 will continue to operate at a higher drive current. For example, for semiconductor dies 310 including or consisting essentially of LEEs, the failure of a device connected in parallel to one or more other devices across the same gap results in the other device(s) operating at a higher current and thus producing light of increased intensity, thereby compensating for the failure of the failed device.

FIG. 3C also illustrates two of the different adhesion schemes described above. One of the semiconductor dies 310 is adhered to the conductive traces 320 via adhesive 360 only at the ends of semiconductor die 310, while between the ends within the gap 370, an optional second adhesive 380 (which is preferably non-conductive) adheres the middle portion of the semiconductor die 310 to substrate 350. In some embodiments the second adhesive 380 is non-conductive and prevents shorting between the two portions of conductive adhesive 360 and/or between conductive traces 320 and/or between the two contacts of semiconductor die 310. As shown, the other semiconductor die 310 is adhered between the conductive traces 320 with adhesive 360 contacting the entirety of the bottom surface of semiconductor die 310. As described above, adhesive 360 is preferably an ACA that permits electrical conduction only in the vertical direction (out of the plane of the page in FIG. 3C) but insulates the conductive traces 320 from each other. In other embodiments, one or more semiconductor dies 310 are adhered between conductive traces 320 within the same gap 370, but there is sufficient “real estate” within the gap 370 (including portions of the conductive traces 320) to adhere at least one additional semiconductor die 310 within the gap 370. In such embodiments, if the one or more semiconductor dies 310 initially adhered within the gap 370 fail, then one or more semiconductor dies 310 (substantially identical to or different from any of the initial semiconductor dies 310) may be adhered within the gap 370 in a “rework” process. For example, referring to FIG. 3C, only one of the depicted semiconductor dies 310 may be initially adhered to the conductive traces 320, and the other semiconductor die 310 may be adhered later, e.g., after failure of the initial die.

As discussed above, two or more semiconductor dies 310 may be connected to the same conductive traces 320 (i.e., within the same gap 370 between conductive traces 320), to provide enhanced functionality. The details of such electrical coupling are discussed in greater detail with reference to FIGS. 40A-40C. In one embodiment the two or more semiconductor dies 310 emit light at two or more different wavelengths, which may be selected to provide improved optical performance, for example to achieve a higher color rendering index. For example, a first semiconductor die may emit in a wavelength range suitable to pump a light-conversion material and a second semiconductor die may emit in a wavelength range outside or partially outside of the emission spectrum of the first semiconductor die and/or the emission spectrum of the light-conversion material. In one embodiment the two or more different wavelengths may be relatively close to each other and the combination of the light from the two or more different wavelengths, for example the dominant wavelength of the combination, may be achieved by a range of wavelengths from each of the two or more semiconductor die. This may result in a reduction in binning requirements for achieving a target chromaticity.

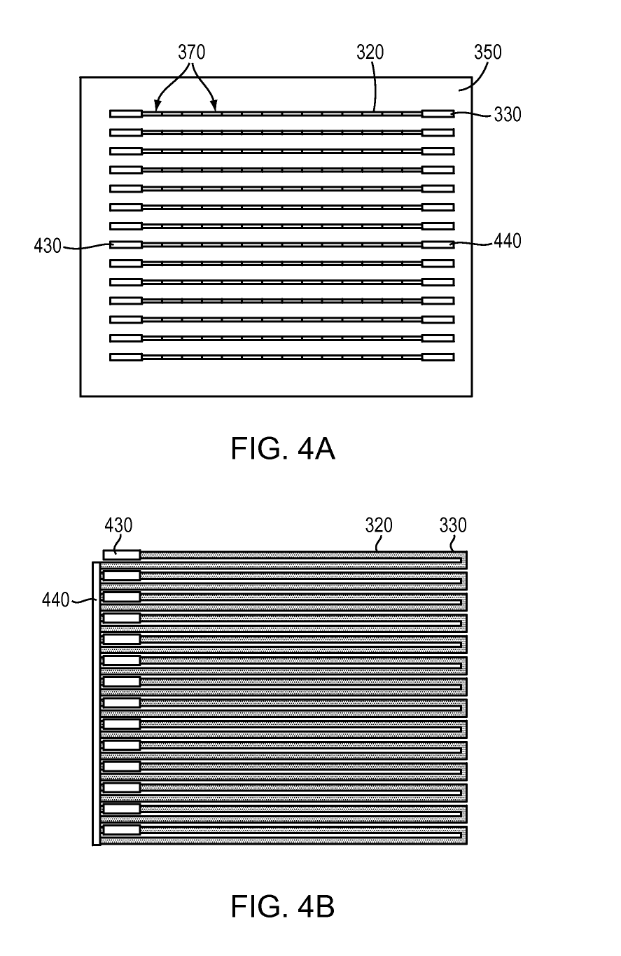

FIGS. 4A and 4B schematically depict two different layouts of conductive traces 320 that may be utilized in electronic devices in accordance with various embodiments of the invention. Much as in FIG. 3A, FIGS. 4A and 4B depict parallel strings 330 of conductive traces 320 configured to interconnect multiple semiconductor dies 310 in series (while the gaps 370 representing bonding locations for the semiconductor dies 310 are shown in FIG. 4A, they are omitted in FIG. 4B for clarity). In FIG. 4A, each string 330 has a contact 430 at one end and a contact 440 at the other. In various embodiments, contact 430 is a “drive” contact for applying operating current or voltage to the semiconductor dies 310, while contact 440 is a “common” or ground contact. In FIG. 4B, each string 330 extends across substrate 350 and turns back to extend back to a point near its starting point, enabling both contacts 430, 440 to be placed on one side of substrate 350. As also shown in FIG. 4B, either or both of contacts 430, 440 for multiple strings 330 may be connected together into a shared contact (as shown of contacts 440 in FIG. 4B); such schemes may simplify layout and interconnection of the semiconductor dies 310 and/or strings 330. While the layouts depicted in FIGS. 4A and 4B position the semiconductor dies 310 in a square or rectangular grid, the semiconductor dies 310 may be arranged in other ways. Likewise, the conductive traces 320 may be substantially straight, as shown, or may be curved, jagged, non-parallel, or arranged in other ways.

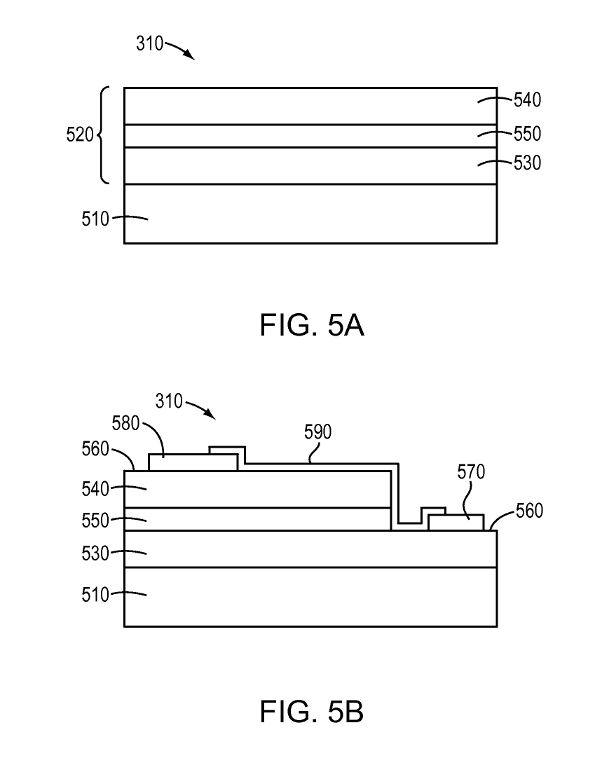

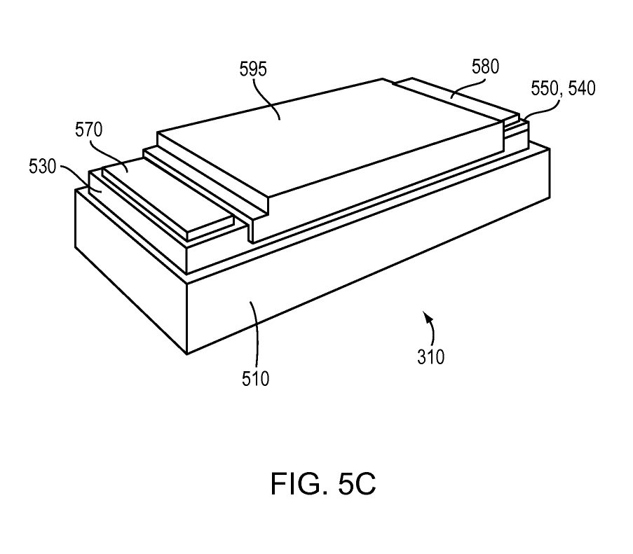

Referring now to FIGS. 5A, 5B, and 5C, the semiconductor die 310 typically includes a substrate 510 with one or more semiconductor layers 520 disposed thereover. In an exemplary embodiment, semiconductor die 310 represents a light-emitting element such as a LED or a laser, but other embodiments of the invention feature one or more semiconductor dies with different or additional functionality, e.g., processors, sensors, detectors, control elements, and the like. Non-LEE dies may or may not be bonded as described herein, and may have contact geometries differing from those of the LEEs; moreover, they may or may not have semiconductor layers disposed over a substrate as discussed below.

Substrate 510 may include or consist essentially of one or more semiconductor materials, e.g., silicon, GaAs, InP, GaN, and may be doped or substantially undoped (e.g., not intentionally doped). In some embodiments substrate 510 includes or consists essentially of sapphire or silicon carbide, however the composition of substrate 510 is not a limitation of the present invention. Substrate 510 may be substantially transparent to a wavelength of light emitted by the semiconductor die 310. As shown for a light-emitting element, semiconductor layers 520 may include first and second doped layers 530, 540, which preferably are doped with opposite polarities (i.e., one n-type doped and the other p-type doped). One or more light-emitting layers 550, e.g., or one or more quantum wells, may be disposed between layers 530 and 540. Each of layers 530, 540, 550 may include or consist essentially of one or more semiconductor materials, e.g., silicon, InAs, AlAs, GaAs, InP, AlP, GaP, InSb, GaSb, AlSb, GaN, AlN, InN, and/or mixtures and alloys (e.g., ternary or quaternary, etc. alloys) thereof. In preferred embodiments, semiconductor die 310 is an inorganic, rather than a polymeric or organic, device. As referred to herein, semiconductor dies 310 may be packaged or unpackaged unless specifically indicated (e.g., a bare-die LED is an unpackaged semiconductor die). In some embodiments, substantially all or a portion of substrate 510 is removed prior to or after the bonding of semiconductor die 310 described below. Such removal may be performed by, e.g., chemical etching, laser lift-off, mechanical grinding and/or chemical-mechanical polishing or the like. In some embodiments all or a portion of substrate 510 is removed and a second substrate—e.g., one that is transparent to or reflective of a wavelength of light emitted by semiconductor die 310—is attached to substrate 510 or semiconductor layer 520 prior to or after the bonding of semiconductor die 310 as described below. In some embodiments substrate 510 includes or consists essentially of silicon and all or a portion of the silicon substrate 510 may be removed prior to or after the bonding of semiconductor die 310 described below. Such removal may be performed by, e.g., chemical etching, laser lift off, mechanical grinding and/or chemical-mechanical polishing or the like.

The structure shown in FIG. 5A is typically processed to fabricate a LEE, as shown in FIG. 5B. In one embodiment, the semiconductor die 310 is patterned and etched (e.g., via conventional photolithography and etch processes) such that a portion of layer 530 is exposed in order to facilitate electrical contact to layer 530 and layer 540 on the same side of semiconductor die 310 (and without, for example, the need to make contact to layer 530 through substrate 510 or to make contact to layer 530 with a shunt electrically connecting a contact pad over layer 540 to layer 530). One or more portions of layers 540, 550 are removed (or never formed) in order to expose a portion of layer 540. Discrete electrical contacts 570, 580 are formed on layers 530, 540, respectively. Electrical contacts 570, 580 may each include or consist essentially of a suitable conductive material, e.g., one or more metals or metal alloys, conductive oxides, or other suitable conductors. In some embodiments, the surface 560 of semiconductor die 310 is non-planar, i.e., contains exposed portions non-coplanar with each other.

In some embodiments, the semiconductor die 310 has a square shape, while in other embodiments semiconductor die 310 has a rectangular shape. In some preferred embodiments, to facilitate bonding (as described below) semiconductor die 310 has a shape with a dimension in one direction that exceeds a dimension in an orthogonal direction (e.g., a rectangular shape), and has an aspect ratio of the orthogonal directions (length to width, in the case of a rectangular shape) of semiconductor die 310 greater than about 1.2:1. In some embodiments, semiconductor die 310 has an aspect ratio greater than about 2:1 or greater than 3:1. The shape and aspect ratio are not critical to the present invention, however, and semiconductor die 310 may have any desired shape. In some embodiments, semiconductor die 310 has one lateral dimension less than 500 μm. Exemplary sizes of semiconductor die 310 may include about 250 μm by about 600 μm, about 250 μm by about 400 μm, about 250 μm by about 300 μm, or about 225 μm by about 175 μm. In some embodiments, semiconductor die 310 includes or consists essentially of a small LED die, also referred to as a “microLED.” A microLED generally has one lateral dimension less than about 300 μm. In some embodiments, semiconductor die 300 has one lateral dimension less than about 200 μm or even less than about 100 μm. For example, a microLED may have a size of about 225 μm by about 175 μm or about 150 μm by about 100 μm or about 150 μm by about 50 μm. In some embodiments, the surface area of the top surface of a microLED is less than 50,000 μ² or less than 10,000 μm².

Because preferred embodiments facilitate electrical contact to contacts 570, 580 via use of a conductive adhesive rather than, e.g., wire bonds, contacts 570, 580 may have a relatively small geometric extent since adhesives may be utilized to contact even very small areas impossible to connect with wires or ball bonds (which typically require bond areas of at least 80 μm on a side). In various embodiments, the extent of one or both of contacts 570, 580 in one dimension (e.g., a diameter or side length) is less than approximately 100 μm, less than approximately 70 μm, less than approximately 35 μm, or even less than approximately 20 μm.

Particularly if semiconductor die 310 includes or consists essentially of a light-emitting device such as an LED or laser, contacts 570, 580 may be reflective (at least to some or all of the wavelengths emitted by semiconductor die 310) and hence reflect emitted light back toward substrate 510. In some embodiments, a reflective contact 580 covers a portion or substantially all of layer 540 and/or a reflective contact 570 covers a portion or substantially all of layer 530. In addition to reflective contacts, a reflector 590 (not shown in subsequent figures for clarity) may be disposed between or above portions of contacts 570, 580 and over portions or substantially all of layer 540 and 530. Reflector 590 is reflective to at least some or all wavelengths of light emitted by semiconductor die 310 and may include various materials. In one embodiment, reflector 590 is non-conductive so as not to electrically connect contacts 570, 580. Reflector 590 may be a Bragg reflector. Reflector 590 may include or consist essentially of one or more conductive materials, e.g., metals such as silver, gold, platinum, etc. Instead of or in addition to reflector 590, exposed surfaces of semiconductor die except for contacts 570, 580 may be coated with one or more layers of an insulating material, e.g., a nitride such as silicon nitride or an oxide such as silicon dioxide. In some embodiments, contacts 570, 580 feature a bond portion for connection to conductive traces 320 and a current-spreading portion for providing more uniform current through semiconductor die 310, and in some embodiments, one or more layers of an insulating material are formed over all or portions of semiconductor die 310 except for the bond portions of contacts 570, 580. FIG. 5C shows a schematic of semiconductor die 310 with an insulating material 595 covering the surface of semiconductor die 310 except for contacts 570, 580. Insulating material 595 may include or consist essentially of, for example, silicon nitride, silicon oxide and/or silicon dioxide. Such insulating material 595 may cover all or portions of the top and sides of semiconductor die 310 as well as portions of the top and sides of layers 530, 540, and 550. Insulating material 595 may prevent shorting between contacts 570 and 580 or between conductive traces 320 (see FIG. 3B), or both during and after the bonding operation.

Referring again to FIGS. 3A, 3B, 3C, semiconductor die 310 typically operates at a current and temperature sufficiently low to prevent melting or other damage to adhesive 360 or to the substrate 350. For example, the operating current of semiconductor die 310 may be less than approximately 50 mA, 10 mA, or in some embodiments 5 mA or less. In some embodiments, the operating current is between approximately 1 mA and approximately 15 mA. The junction temperature of semiconductor die 310 during operation may not exceed approximately 110° C., 100° C., 90° C., or may not exceed 80° C. It should be understood, however, that this is not critical to the present invention and in other embodiments the junction temperature may be any value that does not damage or otherwise adversely affect substrate 350, adhesive 360, or other components of the system. In some embodiments it may be desirable for substrate 350 to withstand higher temperatures, either during processing or operation, and in such embodiments substrates such as polyethylene naphthalate (PEN), for example, may be utilized.

In preferred embodiments, the small size of semiconductor die 310, particularly of an unpackaged semiconductor die 310, and its abovementioned relatively low operating current and temperature, obviate the need for a relatively high thermal conductivity substrate as is conventionally used, for example a ceramic substrate (such as Al₂O₃, AlN or the like) or metal-core printed circuit board (MCPCB) or a discrete or integrated heat sink (i.e., a highly thermally conductive fixture (including, for example, metal or ceramic materials) such as a plate or block, which may have projections such as fins to conduct heat away and into the surrounding ambient) to be in thermal communication with semiconductor die 310. Rather, substrate 350 itself (as well as, e.g., the adhesive, the conductive traces, and even the surrounding ambient itself) provides adequate conduction of heat away from the semiconductor die 310 during operation.

Embodiments of the present invention involve lighting assemblies featuring light-emitting semiconductor dies attached to substrates using adhesives. Such assemblies may include an array of LEEs disposed over substrate 350. In some embodiments, the LEEs are disposed over substrate 350 in a two-dimensional array with a pitch in the range of about 3 mm to about 30 mm. For embodiments employing light-emitting semiconductor dies 310, the overall lighting assembly or module may produce at least 100 lumens, at least 1000 lumens, or even at least 3000 lumens, and/or may have a density of semiconductor die 300 greater than approximately 0.25 die/cm² of area over which the semiconductor die 300 are disposed. Such light-emitting systems may feature semiconductor dies 300 having junction temperatures less than 110° C., 100° C., or even less than 90° C. Also, the heat density of such systems may be less than 0.01 W/cm² of area over which the semiconductor die 300 are disposed. Furthermore, the heat density generated by systems in accordance with embodiments of the invention may be less than approximately 0.01 W/cm², or even less than approximately 0.005 W/cm², whereas conventional light-emitting devices typically have heat densities greater than approximately 0.3 W/cm², or even greater than approximately 0.5 W/cm².

In embodiments in which one or more of the semiconductor dies 310 is an LEE, a phosphor material may be incorporated to shift one or more wavelengths of at least a portion of the light emitted by the die to other desired wavelengths (which are then emitted from the larger device alone or color-mixed with another portion of the original light emitted by the die). As used herein, “phosphor” refers to any material that shifts the wavelengths of light irradiating it and/or that is fluorescent and/or phosphorescent. A phosphor may also be referred to as a light-conversion material. Phosphors are typically available in the form of powders or particles, and in such case may be mixed in binders, e.g., silicone and/or epoxy. As used herein, a “phosphor” may refer to only the powder or particles or to the powder or particles with the binder. In some embodiments, optical elements are incorporated to permit engineering and control of the light distribution pattern.

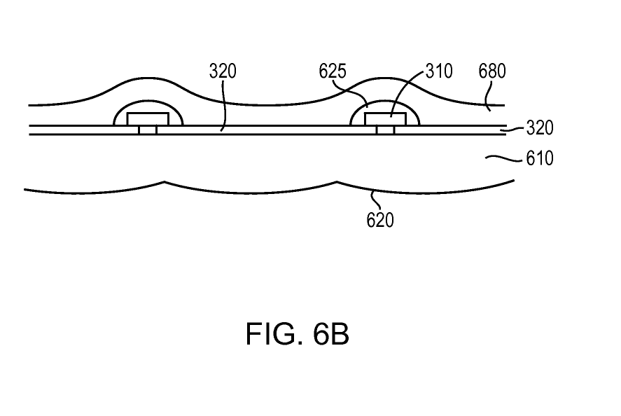

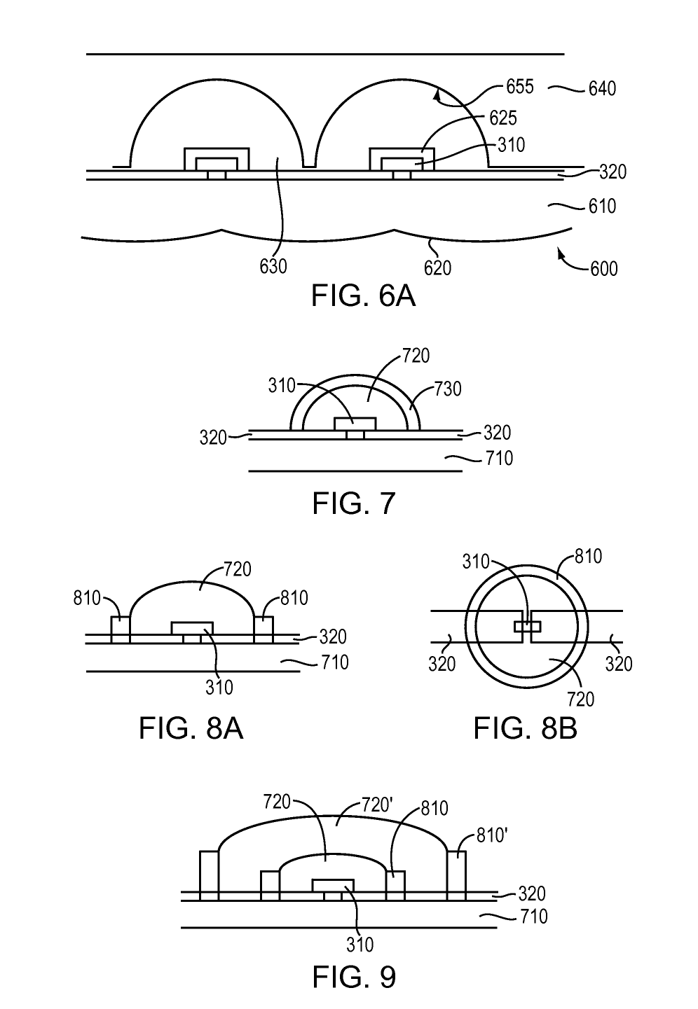

FIG. 6A depicts an example of the integration of phosphors and optical elements with the semiconductor dies 310 according to embodiments of the present invention. FIG. 6A depicts a cross-sectional view of a lighting system 600 featuring an optical substrate 610 having optical elements 620 formed in or on one side thereof and conductive traces 320 formed over the opposite side of optical substrate 610.

Semiconductor dies 310 are disposed over conductive traces 320. Optical substrate 610 thus typically features an array of optical elements 620; in some embodiments, one optical element 620 is associated with each semiconductor die 310, while in other embodiments multiple semiconductor dies 310 are associated with one optical element 620, or multiple optical elements 620 are associated with a single semiconductor die 310. Also shown in FIG. 6A is an optional phosphor 625 and a reflective surface 655 formed over all or a portion of semiconductor die 310 and phosphor 625 and all or a portion of the optical element 620 associated with the semiconductor die 310. The details of the electrical connection of semiconductor dies 310 with conductive traces 320 are omitted from FIG. 6A for clarity.

Conductive traces 320 may include or consist essentially of any conductive material, for example metals such as gold, silver, aluminum, copper and the like, conductive oxides, carbon, etc. Conductive traces 320 may be formed on optical substrate 610 by a variety of means, for example evaporation, physical deposition, plating, lamination, lamination and patterning, electroplating, printing or the like. In some embodiments, conductive traces 320 may be formed by patterning a conductive layer formed over substrate 350, for example by removing a portion of the conductive layer by etching, e.g., wet chemical etching, dry etching, laser etching or the like. In one embodiment, conductive traces 320 are formed using printing, for example screen printing, stencil printing, flexo, gravure, ink jet, or the like. Conductive traces 320 may include or consist essentially of a transparent conductor, for example, a transparent conductive oxide such as indium tin oxide (ITO). Conductive traces 320 may include or consist essentially of a plurality of materials, for example a transparent conductive material in the region of the aperture of reflective surface 655 on optical element 620, and a relatively higher conductivity metallic conductive material outside of this region. This has the advantage of minimizing light loss when light exits the cavity, combined with maintaining a relatively low resistance of conductive trace 320, because the relatively higher resistivity transparent conductor is used only in the region where transparency is desired. Conductive traces 320 may optionally feature stud bumps positioned to align to contacts 312 and 314 of semiconductor dies 310. Conductive traces 320 may have a thickness in the range of about 0.01 μm to about 100 μm. While the thickness of one or more of the conductive traces 320 may vary, the thickness is generally substantially uniform along the length of the conductive trace 320 to simplify processing. However, this is not a limitation of the present invention, and in other embodiments the conductive trace may have a different thickness and/or the conductive trace thickness or material may vary.

Optical substrate 610 may be substantially optically transparent or translucent. For example, optical substrate 610 may exhibit a transmittance greater than 80% for optical wavelengths ranging between approximately 400 nm and approximately 600 nm. Optical substrate 610 may include or consist essentially of a material that is transparent to a wavelength of light emitted by semiconductor dies 310 and/or phosphor 625. Optical substrate 610 may be substantially flexible or rigid. Optical substrate 610 may include or consist essentially of, for example, acrylic, polycarbonate, polyethylene naphthalate (PEN), polyethylene terephthalate (PET), polycarbonate, polyethersulfone, polyester, polyimide, polyethylene, glass, or the like. In some embodiments, optical substrate 610 includes multiple materials and/or layers. Optical elements 620 may be formed in or on optical substrate 610. For example, optical elements 620 may be formed by etching, polishing, grinding, machining, molding, embossing, extruding, casting, or the like. The method of formation of optical elements 620 is not a limitation of embodiments of the present invention. In some embodiments, all or portions of optical substrate 610 and/or optical elements 620 may include one or more layers reflective to a wavelength of light emitted by semiconductor dies 310 and/or phosphor 625.

Optical elements 620 associated with optical substrate 610 may all be the same or may be different from each other. Optical elements 620 may include or consist essentially of, e.g., a refractive optic, a diffractive optic, a total internal reflection (TIR) optic, a Fresnel optic, or the like, or combinations of different types of optical elements. Optical elements 620 may be shaped or engineered to achieve a specific light distribution pattern from the array of light emitters, phosphors and optical elements.

Reflective surface 655 may form a hemispherical or parabolic or other shape. In one embodiment, reflective surface 655 is formed by forming a reflective coating on the interior of a cavity 630 formed in a support substrate 640. Reflective coating 655 may include or consist essentially of a reflective material such as silver, gold, aluminum, copper, etc. In one embodiment, reflective coating 655 includes or consists essentially of a highly reflective white surface, for example, White97 manufactured by WhiteOptics LLC or MCPET manufactured by Furukawa. Reflective surface 655 may be formed by coating all or a portion of the surface of support substrate 640. In one embodiment, reflective surface 655 is formed by forming a depression in a yielding material that already has a reflective surface or coating. The support substrate 640 may include or consist essentially of a flat or substantially flat reflective surface facing semiconductor dies 310. In one embodiment a specular reflective surface 655 may form a parabolic shape and semiconductor dies 310 and/or phosphor 625 may be positioned substantially at the focal point of the parabolic shape, such that the light emitted out of the parabolic shape towards an optical element 620 is substantially collimated in a direction parallel to the axis of the parabolic shape. In some embodiments, the diameter of the aperture of the emitted light is less than about 0.25% of the diameter of optical element 620.

In one embodiment, phosphor 625 is formed over reflective surface 655 instead of around semiconductor dies 310. In one embodiment, a reflective material is formed over the phosphor 625, for example in sheet form, as shown in FIG. 6B. As shown in FIG. 6B, reflective material 680 may include or consist essentially of a coating or a separate material that covers at least a portion of phosphor 625, and, in some embodiments, covers at least a portion of conductive traces 320 and optical substrate 610. In one embodiment, material 680 includes or consists essentially of a white reflective material such as White97 manufactured by WhiteOptics LLC or MCPET manufactured by Furukawa. In one embodiment, the phosphor 625 includes a plurality of materials, as shown and discussed in reference to FIG. 7.

The semiconductor dies 310 may be electrically coupled (or bonded) to conductive traces 320 (and optical substrate 610) using adhesive 360 as shown in FIG. 3C. In some embodiments, during the bonding of semiconductor die 310 to conductive traces 320, adhesive 360 is dispensed in substantially liquid form, i.e., as a paste or a gel, as opposed to a solid such as a tape. The adhesive 360 may be dispensed over portions of semiconductor die 310 (e.g., at least portions of contacts 570, 580 shown in FIG. 5B) or optical substrate 610 (e.g., at least portions of conductive traces 320) or both. Contacts 570, 580 are then brought into physical proximity (or contact) with and adhered to conductive traces 320 via optional application of pressure to semiconductor die 310, optical substrate 610, or both. Because adhesive 360 in some embodiments is a conductive adhesive or an ACA, perfect alignment between contacts 570, 580 and conductive traces 320 is not necessary, thus simplifying the process. (When using an ACA, perfect alignment is not required because conduction occurs only in the vertical direction between contacts 570, 580 and conductive traces 320, and not laterally between contacts 570, 580 or between conductive traces 320.) In one embodiment, semiconductor die 310 and optical substrate 610 are compressed between a substantially rigid surface and a substantially compliant surface.

After or during the optional compression of semiconductor die 310 and optical substrate 610, adhesive 360 is cured by, e.g., application of energy, for example heat and/or ultraviolet light. For example, adhesive 360 may be cured by heating to a temperature ranging from approximately 80° C. to approximately 250° C., for a period of time ranging from approximately several seconds to 1 minute to approximately 30 minutes, depending on the properties of the adhesive.

In another embodiment, adhesive 360 includes or consists essentially of an isotropically conductive adhesive in the region between contacts 570, 580 and their respective conductive traces 320. In such embodiments, in the region between the conductive traces 320 and between contacts 570, 580, insulation may be maintained via absence of adhesive 360 or via the presence of a second, non-conductive adhesive, as shown in FIG. 3C. Adhesive 360 preferably features a polymeric matrix, rather than a fully metallic one that might result in undesirable electrical shorting between contacts 570, 580 and/or between conductive traces 320. In some embodiments adhesive 360 may be reflective to at least some or all wavelengths of light emitted by semiconductor die 310 and/or phosphor 625. It should be noted that other methods of adhering semiconductor dies 310 to substrate 610 and/or conductive traces 320, and/or of electrically coupling semiconductor dies 310 to conductive traces 320 may be utilized, and in other embodiments other methods are used.

Phosphor material 625 may be incorporated to shift the wavelengths of at least a portion of the light emitted by semiconductor dies 310 to other desired wavelengths (which are then emitted from the larger device alone or color-mixed with another portion of the original light emitted by semiconductor dies 310). Exemplary procedures are herein described for integrating phosphors with the semiconductor dies 310 adhered to a substrate 710, as shown in FIG. 7. This process may be utilized for different types of substrates, for example optical substrate 610 described above as well as other types of substrates, described subsequently. For the purpose of the following discussion, it is assumed that the semiconductor die 310 is already attached to substrate 710 and/or portions of conductive traces 320.

Referring to FIG. 7, a phosphor 720 may be formed over semiconductor die 310, for example by a dispensing process, and may optionally include or consist essentially of one or more light-conversion materials such as phosphor powders, quantum dots, or the like within a transparent matrix, and may also feature an optional layer 730. Phosphors vary in composition, and in some embodiments phosphors may include lutetium aluminum garnet (LuAG or GAL), yttrium aluminum garnet (YAG) or other phosphors known in the art. GAL, LuAG, YAG and other materials may be doped with various materials, including, e.g., Ce, Eu, silicates doped with various materials including

Ce, Eu, etc., aluminates, nitrides, and the like. The specific components and/or formulation of the phosphor and/or matrix material are not limitations of the present invention.

The viscosity of the phosphor-infused matrix material may be varied by changing the matrix material and the amount of phosphor within the matrix material. In one embodiment a higher percentage of phosphor in the matrix results in a higher viscosity. The viscosity of the mixture may be adjusted to form the desired shape of phosphor 720 after dispense and curing. Curing may be performed using a variety of techniques, for example, thermal curing or UV curing. In one embodiment the phosphor may be partially cured prior to dispensing to increase its viscosity, in order to achieve a desired shape of phosphor 720. In one embodiment, the phosphor may be heated to a temperature below its cure temperature to reduce its viscosity.

As shown in FIG. 7, the phosphor may include multiple layers of phosphor-infused matrix and/or matrix. That is, the phosphor may include multiple layers, where each layer includes either a phosphor-infused matrix or solely the matrix material. Where multiple layers of phosphor-infused matrix are used, each layer may include different phosphors and/or different matrix materials. In one embodiment a phosphor layer 720 includes only a matrix material that is transparent to a wavelength of light emitted by semiconductor dies 310 and a phosphor layer 730 includes one or more phosphors within a matrix material.

Some embodiments of structures such as those shown in FIGS. 6A, 6B, and 7 may feature one or more containment features 810 to aid in containment of the phosphor-infused matrix material in the region around semiconductor die 310 and to prevent its undesirable spreading. In one embodiment, containment features 810 on substrate 710 are used to aid in containment of the material covering semiconductor dies 310. FIG. 8A shows a side view while FIG. 8B shows a top view of one embodiment where containment features 810 are formed over conductive traces 320. FIG. 8A shows containment feature 810 having a rectangular cross-section, but this is not a limitation of the present invention and in other embodiments containment features 810 have a square, triangular, or an arbitrary profile. FIG. 8B shows a containment feature 810 having a circular shape, but this is not a limitation of the present invention and in other embodiments containment feature 810 has a rectangular, square, hexagonal, or an arbitrary shape. In one embodiment containment feature 810 has a height in the range of about 0.5 μm to about 500 μm. In one embodiment, the containment feature 810 has a length or diameter ranging from about 100 μm to about 5000 μm. In one embodiment, containment feature 810 includes a structure that is attached to substrate 710, for example a ring. Containment feature 810 may be printed. In one embodiment containment feature 810 is printed in the same step using the same material as that of conductive traces 320. Alternatively, containment feature 810 may be printed in a separate step from that used to form conductive traces 320 and may include the same or different material as that of conductive traces 320. FIGS. 8A and 8B show one containment feature but this is not a limitation of the present invention and in other embodiments multiple containment features are used. In one embodiment, multiple concentric containment features are used. Containment feature 810 may be printed using a non-conductive material over conductive traces 320. In one embodiment, the containment feature 810 is reflective to a wavelength of light emitted either by semiconductor dies 310 or phosphor 720 or both.

Multiple containment features 810 may be used to build up a plurality of layers of material over semiconductor dies 310. For example, as shown in FIG. 9, semiconductor die 310 is surrounded by first containment feature 810 and second containment feature 810′. Material 720 may be contained by first containment feature 810 and material 720′ may be contained by second containment feature 810′. In one embodiment, material 720 includes a transparent material and material 720′ includes a light-conversion material. FIG. 9 shows two layers, but this is not a limitation of the present invention and in other embodiments more than two layers are utilized. For example, a first layer may include a transparent material, a second layer may include a first light-conversion material and a third layer may include a second light-conversion material, where the first and second light-conversion materials are not the same. This may be useful in situations where it is desirable to separate two different light-conversion materials to reduce absorption of the light emitted by one light-conversion material by the other light-conversion material.

In another embodiment, containment features 810 include a coating over all or a portion of semiconductor die 310 to enhance the positioning of light-conversion material 720 over semiconductor die 310, or include a coating surrounding semiconductor dies 310 to aid in containment of light-conversion material 720 over semiconductor dies 310. Containment feature 810 may include a low-surface-tension coating, for example a fluorocarbon such as NyeBar manufactured by Nye Lubricants. In one embodiment, containment feature 810 includes a hydrophobic coating or a hydrophilic coating. In one embodiment containment feature 810 includes a perfluoro siloxane. Such coatings may be applied by brush, printing, for example printing, screen printing, flexo, gravure, ink jet or the like, dispensing, spraying or any other method. Containment feature 810 may include a coating to increase the contact angle of light-conversion material 720 on substrate 710. It is to be understood in this discussion that light-conversion material 720 may include a transparent material, a light-conversion material, or a material that provides scattering or diffusion of light emitted by semiconductor dies 310. In one embodiment light-conversion material 720 is formed by molding, for example compression molding.

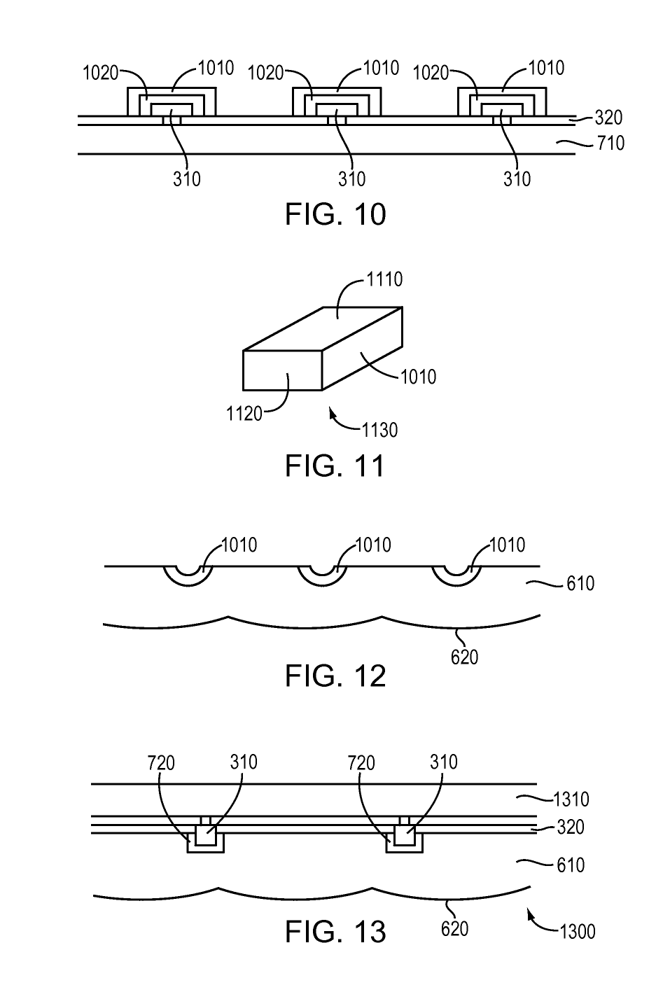

In one embodiment, light-conversion material 720 is formed in small “caps” that are disposed over each semiconductor die 310. FIGS. 10 and 11 depict one example of such a cap 1010 having a top surface 1110, side surfaces 1120 and bottom 1130. Bottom 1130 may be completely or partially open to permit cap 1100 to fit entirely or partially over semiconductor die 310, as shown in FIG. 10. FIGS. 10 and 11 show caps 1010 having a square or rectangular shape, but this is not a limitation of the present invention and in other embodiments cap 1010 may be hexagonal, circular, elliptical, or any other shape. FIGS. 10 and 11 show caps 1010 having a flat top, but this is not a limitation of the present invention and in other embodiments cap 1010 may be shaped like a hemisphere, cone, pyramid or have any other arbitrary shape or top shape. FIGS. 10 and 11 show caps 1010 having space 1020 between semiconductor dies 310 and phosphor cap 1010, but this is not a limitation of the present invention and in other embodiments space 1020 may be eliminated or may include a material different from cap 1010. In one embodiment space 1020 may include a material transparent to a wavelength of light emitted by semiconductor die 310. In one embodiment space 1020 includes a material transparent to a wavelength of light emitted by semiconductor die 310 having a refractive index of at least about 1.3, and preferably above about 1.4. In one embodiment caps 1010 may be disposed in depressions formed in optical substrate 610 opposite optical elements 620, as shown in FIG. 12. In FIG. 12 caps 1010 are shown as hemispherical, but this is not a limitation of the present invention and in other embodiments caps 1010 may have any shape. Caps 1010 may be attached to a substrate 710 (see FIG. 10) using a variety of techniques, for example using an adhesive or glue or using a clamp or socket. In one embodiment, the space between cap 1010 and semiconductor die 310 is partially or completely filled with a material that adheres cap 1010 to substrate 710 and or semiconductor die 310. For example the space between cap 1010 and semiconductor die 310 may be partially or completely filled with a transparent encapsulating matrix material that not only adheres cap 1010 to substrate 710, but that also aids in reducing TIR losses in semiconductor die 310, for example by having an index of refraction of, e.g., at least about 1.3, and preferably above about 1.4.

Cap 1010 may be attached to optical substrate 610 (see FIG. 12) using a variety of techniques, for example using an adhesive or glue or using a clamp or socket. In one embodiment the cap 1010 is press-fit into a depression in optical substrate 610.

Cap 1010 may be formed using a variety of methods, for example injection molding, casting, machining, embossing or molding of a starting sheet or other techniques. In one embodiment, cap 1010 includes a support structure onto which light-conversion material 720 may be formed or deposited. Support substrate 640 (see FIG. 6A) and optical substrate 610 may be mated in a variety of ways. In one embodiment, support substrate 640 is attached to optical substrate 610 by an adhesive, a UV- or heat-cured adhesive, physical fasteners or the like. For example an adhesive may be formed by spraying, spinning, spreading (for example using a Mayer bar or draw down bar), or may be in tape form, or may be deposited using a doctor blade technique, or by printing. The adhesive may cover substantially all of the mating surfaces or only one or more portions of the mating surfaces. In one embodiment, a material used to mate support substrate 640 and optical substrate 610 is preferably transparent to a wavelength of light emitted by semiconductor dies 310 and/or light-conversion material 625. More than one material may be used to mate support substrate 640 and optical substrate 610. FIG. 13 illustrates another embodiment of the present invention in which light-conversion material 720 is formed in a well in optical substrate 610 that is aligned to optical element 620 during the manufacture of optical substrate 610. For example, in one embodiment the wells and optical elements 620 are formed simultaneously in the manufacturing process of optical substrate 610, for example using a molding or embossing process. The wells may be formed before or after formation of optical elements 620, but the wells are aligned relative to optical elements 620. It should be noted that alignment of the wells relative to optical elements 620 may mean that the center of the well is aligned to the center of optical element 620; however, this is not a limitation of the present invention and in other embodiments alignment refers to a specified relationship between the geometry of the wells and the geometry of optical elements 620. A resulting advantage of this approach is the elimination of the need for any alignment between light-conversion material 720 and optical element 620 in subsequent manufacturing steps. Semiconductor dies 310 are electrically coupled to conductive traces 320 formed over emitter substrate 1310, which may then be mated with optical substrate 610, resulting in semiconductor dies 310 being surrounded by light-conversion material 720.

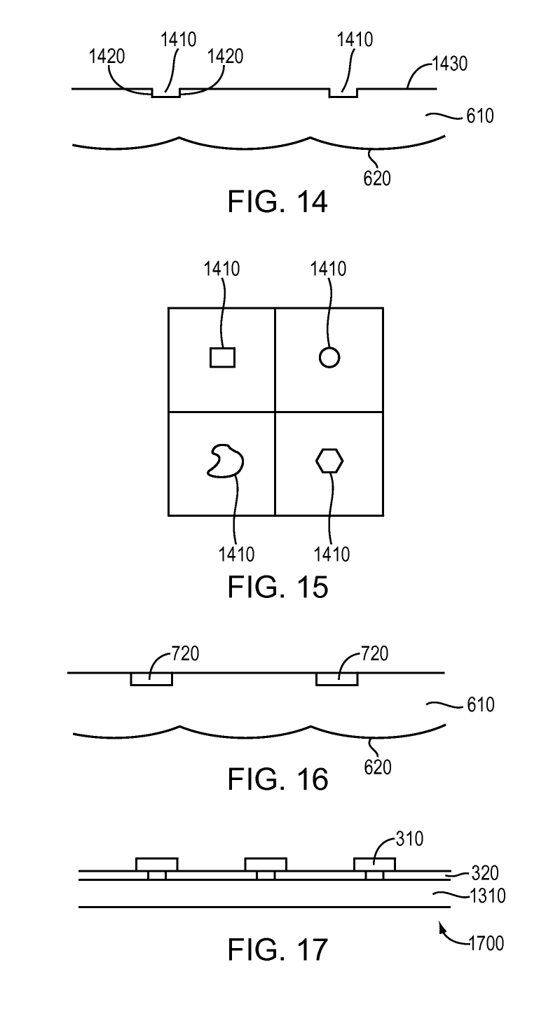

FIG. 14 shows the structure of FIG. 13 at an early stage of manufacture, including optical substrate 610, optical elements 620, and wells 1410 into which light-conversion material 720 is to be formed. Optical substrate 610 may be substantially optically transparent or translucent. For example, optical substrate 610 may exhibit a transmittance greater than 80% for optical wavelengths ranging between approximately 400 nm and approximately 600 nm. Optical substrate 610 may include a material that is transparent to a wavelength of light emitted by semiconductor dies 310 and/or phosphor 720. Optical substrate 610 may be substantially flexible or rigid. Optical substrate 610 may include, for example, acrylic, polycarbonate, polyethylene naphthalate (PEN), polyethylene terephthalate (PET), polycarbonate, polyethersulfone, polyester, polyimide, polyethylene, glass or the like. In some embodiments, optical substrate 610 includes a plurality of materials and/or layers.

Optical elements 620 and wells 1410 may be formed simultaneously or sequentially. In one embodiment, optical elements 620 and/or wells 1410 are formed by removal of a portion of the material of optical substrate 610, for example by drilling, milling, sand blasting, etching or the like. Optical elements 620 and/or wells 1410 may be formed in or on optical substrate 610. For example optical elements 620 and/or wells 1410 may be formed by etching, polishing, grinding, machining, molding, embossing, casting drilling abrasive blasting or the like. The method of formation of optical elements 620 and/or wells 1410 is not a limitation of the present invention. Alignment of the geometry of wells 1410 and optical elements 620 may be achieved by a variety of methods known to those skilled in the art and without undue experimentation.

Optical elements 620 associated with optical substrate 610 may all be the same or may be different. Optical elements 620 may include for example a refractive optic, a diffractive optic, a total internal reflection (TIR) optic, a Fresnel optic or the like, or combinations of different types of optical elements. Optical elements 620 may be shaped or engineered to achieve a specific light distribution pattern from the array of light emitters, phosphors and optical elements.

Wells 1410 are shown as having a square or rectangular cross-section in FIG. 14; however, this is not a limitation of the present invention and in other embodiments wells 1410 have any cross-section. For example, sidewalls 1420 of wells 1410 are shown as being perpendicular to surface 1430 of optical substrate 610, however this is not a limitation of the present invention and in other embodiments sidewalls 1420 make an acute or obtuse angle with surface 1430 or have any arbitrary shape.

Wells 1410 may have any shape, as shown in top view in FIG. 15, which shows square, circular, hexagonal and freeform shapes for well 1410. The shape of well 1410 is not a limitation of the present invention and in other embodiments well 1410 has any shape.

FIG. 16 shows the structure of FIG. 14 at a later stage of manufacture. As shown, light-conversion material 720 may be formed in wells 1410. Light-conversion material 720 may fill well 1410, or well 1410 may be underfilled or overfilled. Light-conversion material 720 may be formed in wells 410 by a variety of techniques. In one embodiment, light-conversion material 720 is dispensed in wells 1410. In one embodiment, light-conversion material 720 is introduced into the wells by a doctor blade technique. However, the technique by which light-conversion material 720 is formed in wells 1410 is not a limitation of the present invention. As discussed above, the light-conversion material 720 may include one homogeneous material, a combination of a phosphor and a matrix, the matrix material alone, multiple layers of different materials or any arbitrary distribution of said materials.

A second component of structure 1300 shown in FIG. 13 is lightsheet 1700 including substrate 1310, conductive traces 320, and semiconductor dies 310, as shown in

FIG. 17. As discussed with reference to FIGS. 3A-3C, 4A, 4B, and 6A and 6B, semiconductor dies 310 may be electrically coupled to conductive traces 320 using an adhesive (not shown in FIG. 17 for clarity), e.g., an ACA; however, this is not a limitation of the present invention and in other embodiments semiconductor dies 310 are electrically coupled to conductive traces 320 by other techniques and/or materials. In one embodiment, semiconductor dies 310 may be bare LED dies. In one embodiment, semiconductor dies 310 may be packaged LEDs.

Lightsheet substrate 1310 may include or consist essentially of a semicrystalline or amorphous material, e.g., polyethylene naphthalate (PEN), polyethylene terephthalate (PET), polycarbonate, polyethersulfone, polyester, polyimide, polyethylene, and/or paper. Lightsheet substrate 1310 may be substantially flexible, substantially rigid or substantially yielding. In some embodiments, the substrate is “flexible” in the sense of being pliant in response to a force and resilient, i.e., tending to elastically resume an original configuration upon removal of the force. A substrate may be “deformable” in the sense of conformally yielding to a force, but the deformation may or may not be permanent; that is, the substrate may not be resilient. Flexible materials used herein may or may not be deformable (i.e., they may elastically respond by, for example, bending without undergoing structural distortion), and deformable substrates may or may not be flexible (i.e., they may undergo permanent structural distortion in response to a force). The term “yielding” is herein used to connote a material that is flexible or deformable or both.

Lightsheet substrate 1310 may include multiple layers, e.g., a deformable layer over a rigid layer, for example, a semicrystalline or amorphous material, e.g., PEN, PET, polycarbonate, polyethersulfone, polyester, polyimide, polyethylene, and/or paper formed over a rigid substrate for example including, acrylic, aluminum, steel and the like. Depending upon the desired application for which embodiments of the invention are utilized, lightsheet substrate 1310 may be substantially optically transparent, translucent, or opaque. For example, lightsheet substrate 1310 may be reflecting or transmitting. In one embodiment lightsheet substrate 1310 exhibits a transmittance or a reflectivity greater than 80% for optical wavelengths ranging between approximately 400 nm and approximately 700 nm. In some embodiments lightsheet substrate 1310 exhibits a transmittance or a reflectivity of greater than 80% for one or more wavelengths emitted by semiconductor die 310 and/or light-conversion material 720. Lightsheet substrate 1310 may also be substantially insulating, and may have an electrical resistivity greater than approximately 100 ohm-cm, greater than approximately 1×10⁶ ohm-cm, or even greater than approximately 1×10¹⁰ ohm-cm.

Optical substrate 610 with light-conversion material 720 may then be mated with lightsheet 1700, as shown in FIG. 13, where semiconductor dies 310 are substantially aligned with and fully or partially immersed in light-conversion material 720 in wells 1410 in any of a number of different ways. In one embodiment, well 1410 is underfilled with light-conversion material 720, such that after mating substantially all of well 1410 is filled with the combination of semiconductor dies 310 and light-conversion material 720.

In one embodiment, well 1410 is underfilled, filled, or overfilled with light-conversion material 720, such that after mating substantially all of well 1410 is filled with the combination of semiconductor dies 310 and light-conversion material 720, and an excess portion of light-conversion material 720 is forced from well 1410 to occupy a portion of the space between lightsheet 1700 and optical substrate 610. The excess portion of light-conversion material 720 that is forced from well 1410 to occupy a portion of the space between lightsheet 1700 and optical substrate 610 may act to hold lightsheet 1700 and optical substrate 610 together. In one embodiment, well 1410 has one or more void spaces that are not filled with either semiconductor dies 310 or light-conversion material 720.

The size of semiconductor dies 310 may be smaller than well 1410 and a modest amount of misalignment of the center of semiconductor dies 310 with the center of well 1410 may be acceptable. To aid in alignment, alignment features, for example alignment marks or pins or holes or other features on optical substrate 610 that mate or align to corresponding features on lightsheet 1700 may be used. Such alignment features may be formed on optical substrate 610 at the same time or a different time from the formation of wells 1410 and/or optical elements 620. Similarly, such alignment features on lightsheet 1700 may be formed at the same time or a different time as conductive traces 320.

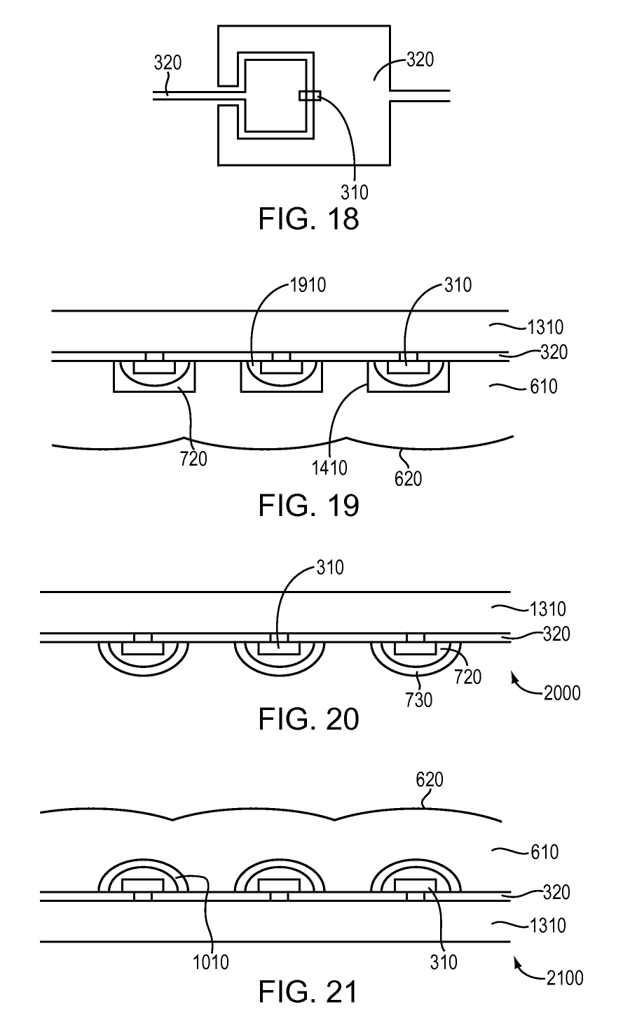

In one embodiment, a reflective surface is formed on the back or front of lightsheet substrate 1310, so that any light emitted out the back side (i.e., the side adjacent to lightsheet substrate 1310) of semiconductor dies 310 is reflected back toward light-conversion material 720. Such a reflective coating may include a metal such as gold, silver, aluminum, copper or the like and may be deposited by evaporation, sputtering, chemical vapor deposition, plating, electroplating or the like. If the reflective coating is on the same side as conductive traces 320, the reflective coating may be electrically isolated from conductive traces 320 or may be removed in the regions occupied by conductive traces 320. The reflective coating may be formed either over or under conductive traces 320. The reflective coating may cover all or portions of lightsheet substrate 1310 and/or conductive traces 320. The reflective coating may also include other materials, e.g., a Bragg reflector, or one or more layers of a specular or diffuse reflective material. In one embodiment, lightsheet substrate 1310 is backed with a reflective material, for example any one as discussed above, or, e.g., White97 manufactured by WhiteOptics LLC or MCPET manufactured by Furukawa, or any other reflective material. In one embodiment lightsheet substrate 1310 includes or consists essentially of a material that is reflective to a wavelength of light emitted by semiconductor dies 310, for example white PET, white paper, MCPET, White97 or the like. In one embodiment, conductive traces 320 include a material reflective to a wavelength of light emitted by semiconductor dies 310 and/or light-conversion material 720 and are patterned to provide a region of reflective material surrounding semiconductor dies 310, as shown in FIG. 18. In one embodiment, one or more materials are formed over all or portions of semiconductor dies 310 prior to mating with optical substrate 610. The semiconductor dies 310 may be all or partially coated with a transparent material 1910 having a refractive index of at least 1.3, preferably at least 1.4, to decrease total internal reflection losses in semiconductor dies 310, as shown in FIG. 19. Such an embodiment provides spatial separation between light-conversion material 720 and semiconductor dies 310, which may result in reduced heating of light-conversion material 720. Reduced heating of light-conversion material 720 may be desirable because it may result in reducing the efficiency loss and wavelength shift associated with higher light-conversion material temperatures.

The lightsheet and optical substrate 610 may be mated in a variety of ways, as discussed above, or by other means. In one embodiment, mating is achieved by using an adhesive, a UV- or heat-cured adhesive, physical fasteners or the like. For example, an adhesive may be formed by spinning, spreading (for example using a Mayer bar or draw down bar), spraying, or may be in tape form, or may be deposited using a doctor blade technique, or by printing. The adhesive may cover substantially all of the mating surfaces or only one or more portions of the mating surfaces. In one embodiment the adhesive is transparent to a wavelength of light emitted by semiconductor dies 310 and/or light-conversion material 720. More than one material may be used to mate support the lightsheet and optical substrate 610. The adhesive over semiconductor dies 310 may have a low surface energy relative to the material in well 1410, and may thus be self-aligning, i.e., providing a driving force for a shift of the covered semiconductor dies 310 relative to the material in well 1410 causing these to align, for example by minimization of surface energy. In some embodiments, the lightsheet and optical substrate 610 are mated by means other than an adhesive, for example using mechanical fasteners, clamps, screws or the like, tape, or by other means. In one embodiment, material 720 shown in FIG. 19 includes a transparent material, and material 1910 shown in FIG. 19 may include a light-conversion material, as discussed with reference to FIGS. 7-11. In such an embodiment, a lightsheet 2000, as shown in FIG. 20, emits white (or other desired mixed-color) light because a light-conversion material is formed over semiconductor dies 310 prior to mating with optical substrate 610. In one embodiment, materials 720 and 730 are formed over semiconductor dies 310, as shown in FIG. 7, prior to mating with optical substrate 610, where material 720 may include a transparent material that is transparent to a wavelength of light emitted by semiconductor dies 310, and material 730 may include a light-conversion material. A schematic of this embodiment, identified as lightsheet 2000, is shown in FIG. 20. As discussed above, this arrangement may provide reduced heating of light-conversion material 730 by semiconductor dies 310. A second advantage of this embodiment is that lightsheet 2000 may be used for both direct- and indirect-view luminaires. In direct-view luminaires, it may be important to have optics to not only provide a specific light distribution but also to provide an aesthetically pleasing look to the luminaire when it is off and/or on. For indirect-view applications, for example, where the light is incident on the ceiling or hidden behind a cover, the light-emitting surface is generally not in direct view and thus its appearance is less important and optics may not be necessary. In this case, lightsheet 2000 may be used without additional optics, as shown in FIG. 20. Lightsheet 2000 may be further mated with optical substrate 610 when required, where wells 1410 may be filled with a transparent material. In some embodiments, wells 1410 are all or partially filled with a transparent or light-conversion material, or are unfilled.

It is important to note that alignment of optical elements 620 to well 1410 does not necessarily mean alignment of the center of optical elements 620 to the center of well 1410, but that their relative positions may be accurately and reproducibly controlled and manufactured. In other words, center-to-center alignment is not a limitation of this invention.

FIG. 21 depicts a schematic of a lighting system 2100 that includes lightsheet 1700 or lightsheet 2000 and optical substrate 610, where caps 1010 including a light-conversion material are disposed in matching depressions in optical substrate 610, as described with reference to FIG. 12. In one embodiment, the space between semiconductor dies 310 and cap 1010 is empty, i.e., filled with air or another gas or fluid.

In one embodiment, the space between semiconductor dies 310 and cap 1010 is completely or partially filled with a matrix material or encapsulant that is transparent to a wavelength of light emitted by semiconductor dies 310. The encapsulant may aid in reducing TIR losses in semiconductor dies 310 and may also be used to adhere or help adhere optical substrate 610 to lightsheet substrate 1310. The light emitters of lightsheet 1700 may be partially or completely coated with a matrix material or encapsulant transparent to a wavelength of light emitted by semiconductor dies 310 prior to mating with optical substrate 610.

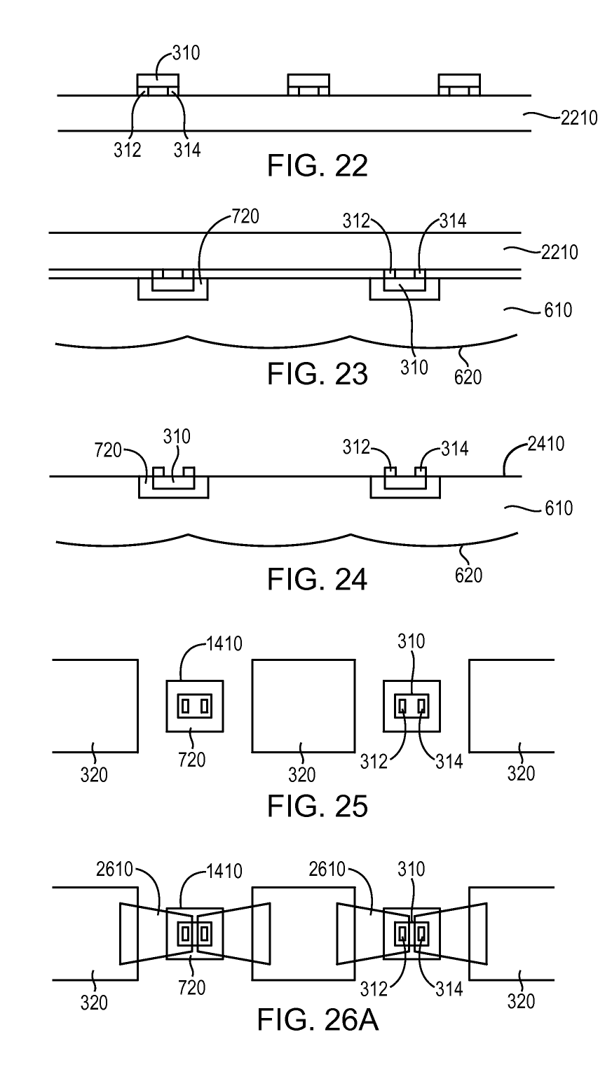

In yet another embodiment, the structure starts with that shown in FIG. 16, where wells 1410 are completely or partially filled with light-conversion material 720 and wells 1410 are aligned with optical elements 620. Semiconductor dies 310 are attached with contacts 312 and 314 down (that is facing) toward a temporary substrate 2210, as shown in FIG. 22. Semiconductor dies 310 are preferably arranged on temporary substrate 2210 in an array pattern matching that of wells 1410 in optical substrate 610. In the next step of manufacture, optical substrate 610 and temporary substrate 2100 are mated together such that semiconductor dies 310 are partially or fully immersed in light-conversion material 720, as shown in FIG. 23. Light-conversion material 720 may be completely or partially cured or solidified at this point in the process, for example by curing using heat, UV radiation or other techniques. Temporary substrate 2210 is then removed, leaving the structure shown in FIG. 24. FIG. 24 shows semiconductor dies 310 with their electrical contacts exposed, i.e., not covered by light-conversion material 720. In some embodiments, contacts 312, 314 undergo one or more additional steps to remove residual light-conversion material 720 from over all or a portion of contacts 312, 314 to enable subsequent electrical contact thereto. In one embodiment, the semiconductor dies 310 may include LEDs having one or more reflectors over a portion or substantially all of their surfaces (of the contact side); these reflectors reflect light emitted by the active region of the LED into light-conversion material 720 rather than out the top (contact) side of semiconductor dies 310. As shown in FIG. 24, the structure at this point in manufacture includes multiple semiconductor dies 310 partially embedded in light-conversion material 720, but with electrical contacts 312, 314 exposed and substantially coplanar with the surface 2410 of optical substrate 610. In some embodiments, the height difference between electrical contacts 312, 314 and surface 2410 may be less than 25 μm, or less than 10 μm, or less than 5 μm, or even less than 2 μm; however, the height difference between electrical contacts 312, 314 and surface 2410 is not a limitation of the present invention.

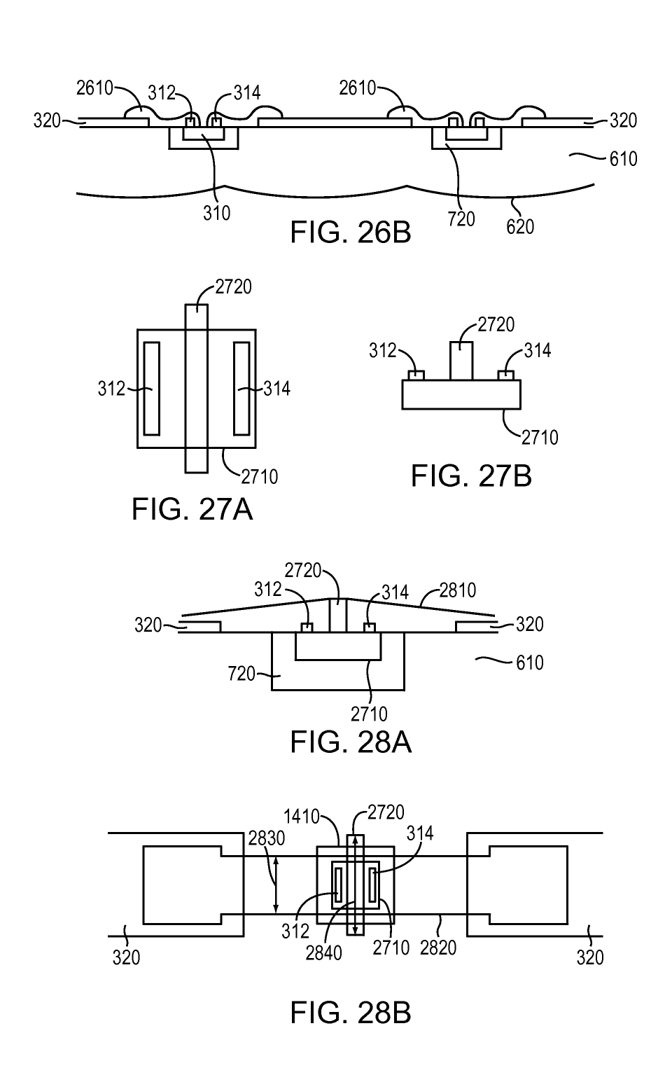

In one embodiment, optical substrate 610 has conductive traces 320 formed thereon prior to mating with temporary substrate 2210, as shown in the schematic top view in FIG. 25. Such conductive traces may be formed as described previously. Semiconductor dies 310 may then be electrically coupled to conductive traces 320 by jumpers 2610, as shown in FIG. 26A and 26B (top and side view respectively) to form a string of electrically coupled light-emitting elements, for example a series-connected string of LEDs. Jumpers 2610 may be formed by a variety of different techniques. In one embodiment, conductive material is formed and patterned over the surface of optical substrate 610, for example by evaporation, sputtering, plating or the like, and patterning may be performed using photolithography, shadow mask, stencil mask or the like. In one embodiment, jumpers 2610 are formed by printing, for example by screen printing, stencil printing, ink jet printing or the like. Jumpers 2610 are shown as having a somewhat trapezoidal shape in FIG. 26A, but this is not a limitation of the present invention and in other embodiments jumpers 2610 have rectangular, square or any arbitrary shape. Jumpers 2610 may include one or more conductive materials, for example aluminum, gold, silver, platinum, copper, carbon, conductive oxides or the like. Jumper 2610 may have a thickness in the range of about 50 nm to about 50 μm. In one embodiment jumper 2610 has a thickness in the range of about 100 nm to about 10 μm. In one embodiment, jumpers 2610 include materials used for conductive traces 320 and/or are formed using methods used for forming conductive traces 320. In one embodiment jumper 2610 includes or consists essentially of a conductive tape or wire. In one embodiment jumper 2610 includes or consists essentially of a conductive paste, liquid or gel that may optionally be subsequently cured to form a solid or gel or material with an arbitrary viscosity.

Since the semiconductor dies 310 may be relatively small, for example on the order of about 300 μm by about 300 μm or smaller, and contacts 312, 314 on semiconductor dies 310 are even smaller, on the order of linear dimensions of about 80 μm or less, the ability to form and align small jumpers 2610 is an advantageous aspect of embodiments of the present invention. Jumper 2610 may have a length on the order of about 0.2 mm to about 5 mm and a width of about 20 μm to about 2 mm. The width in particular may have substantial variation if a trapezoidal shape, or a shape that has different widths at each end, is used, where the width is relatively small at the end coupling semiconductor dies 310 and relatively wide at the end coupling to conductive trace 320. Ink jet printing of conductive traces may achieve the required positional accuracies as well as resolution and is one implementation of this embodiment. However, ink jet printing is a serial process and thus may have relatively higher costs associated with relatively low throughput. In some embodiments it is desirable to have lower costs, which may be achieved through batch formation of jumpers 2610.

Jumpers 2610 may be printed, for example using a batch-type printing process such as screen printing, stencil printing, gravure or flexo printing. A relatively high level of resolution and/or accuracy may be required of these printing methods, particularly for relatively smaller light-emitting elements. For example, in one embodiment a semiconductor die 310 includes an LED with dimensions of about 200 μm by about 200 μm. If, for example, the electrical contacts extend in from opposite sides of the LED by about 50 μm, then the gap between contacts is about 100 μm. The jumper formation process may thus be capable of forming conductive traces with a gap less than about 100 μm in extent, for example less than about 75 or about 50 μm. Furthermore, the placement accuracy of the jumper is also on the order of about 75 μm or about 50 μm.

While many of the formation technologies, and in particular printing technologies, are capable of the resolution and accuracy discussed above, that resolution and accuracy come at a relatively higher cost, compared to the same processes but with lower resolution and accuracy. For example relatively higher resolution may be achieved in screen printing using high resolution screens and emulsions, for example synthetic fabric or metal screens. Such screens may require higher tension and additional equipment to mount the screens. Printing tools may be equipped with vision systems to achieve higher accuracy in alignment, for example alignment of jumper 2610 to the contacts of semiconductor die 310.

It may be desirable from a cost perspective to use relatively lower-resolution and/or less-accurate formation methods to, e.g., form jumper 2610 or other features. In one embodiment jumper 2610 is formed by a self-aligned method. This approach starts with a modification to the semiconductor die. A modified semiconductor die 2710 is shown in FIG. 27A and B in plan view and cross-section respectively. Semiconductor die 2710 includes contacts 312, 314 and barrier 2720. Barrier 2720 is taller than contacts 312, 314 and may include any of a variety of materials. FIG. 27A shows barrier 2720 extending past the edges of semiconductor die 2710 but this is not a limitation of the present invention and in other embodiments barrier 2720 ends at the edges of semiconductor die 2710 or does not extend all the way to the edges of semiconductor die 2710. Barrier 2720 may be fabricated as part of the semiconductor die fabrication process, for example where the semiconductor die includes an LED, the LEDs are fabricated on a wafer and barrier 2720 may be fabricated when the LEDs are in wafer form, before singulation. Barrier 2720 may include insulating or conductive materials, for example photoresist, polyimide, oxide, nitride, metals such as gold, copper, aluminum, silver or the like, or a semiconductor. In one embodiment barrier 2720 is formed after the fabrication of the semiconductor die.

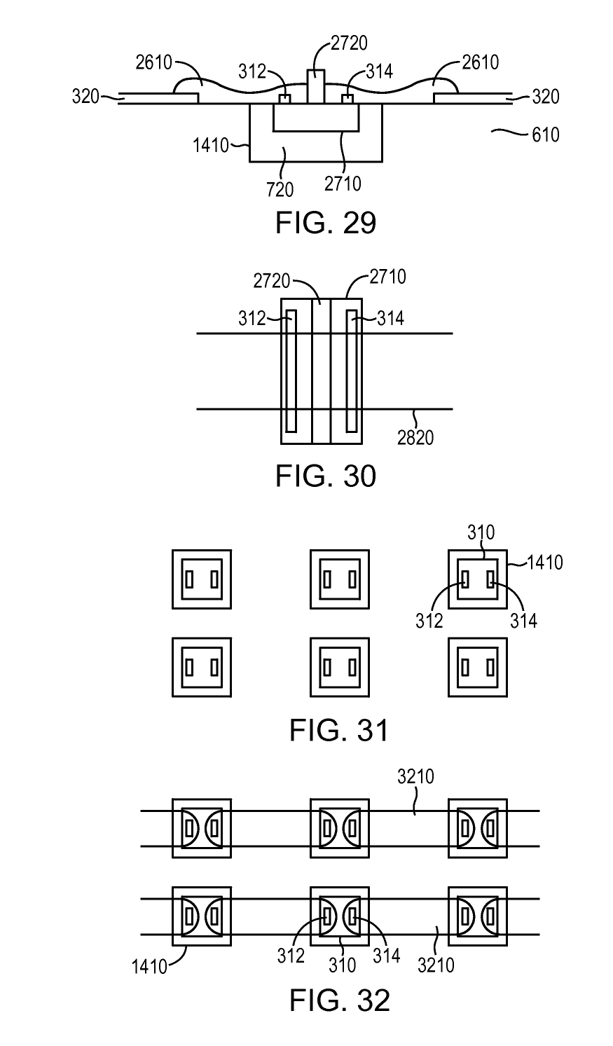

During the printing process, barrier 2720 acts to prevent ink that will form jumpers 2610 from being deposited between contacts 312 and 314, as shown in FIG. 28A. A screen 2810 for screen printing is held above the surface semiconductor dies 2710 by barrier 2720, and barrier 2720 prevents the ink that will form jumpers 2610 from connecting contacts 312 and 314. The top view in FIG. 28B shows a mask or screen opening 2820, which in this embodiment does not require a small gap between contacts 312 and 314 to prevent electrical connection between contacts 312 and 314, thus reducing the resolution requirement on the printing process. FIG. 29 shows a cross-sectional view after printing, showing jumpers 2610 overlying contacts 312 and 314 and electrically coupling them to conductive traces 320.

FIGS. 27-29 show barrier 2720 having a rectangular cross-section, but this is not a limitation of the present invention and in other embodiments barrier 2720 has other cross-sections, for example square, triangular, trapezoidal or any arbitrary shape. Barrier 2720 may be translucent, opaque or transparent to a wavelength of light emitted by light emitter 2720. In some embodiments, barrier 2720 is removed after the interconnect process, while in other embodiments barrier 2720 remains through subsequent parts of the process or even remains in place in the finished structure.

Alignment tolerances may be reduced by several approaches. First, as shown in FIG. 27, barrier 2720 may extend past the edges of semiconductor die 2710. The width of the opening in mask 2820 in the semiconductor die 2710 region (width 2830) is less than the length 2840 of barrier 2720, and thus there is increased tolerance on the positional accuracy required of mask 2820 relative to semiconductor die 2710.

In another embodiment shown in FIG. 30, semiconductor die 2710 has a width relatively larger than its length (where the width is the direction parallel to barrier 2720). In this embodiment the width 2830 of mask 2820 (see FIG. 28B) may be less than the width of semiconductor die 2710 and thus there is increased tolerance on the positional accuracy for mask 2820 relative to semiconductor die 2710. FIG. 30 shows mask 2820 offset from the center of semiconductor die 2710. Note that in FIG. 30 contacts 312 and 314 also have a large aspect ratio, that is they are long and skinny to maximize the overlap with jumper 2610 and minimize the size of semiconductor die 2710.

While semiconductor die 2710 and contacts 312 and 314 are shown as rectangular this is not a limitation of the present invention and in other embodiment they have other shapes, for example square, triangular, hexagonal or any other shape. In some embodiments the shape is determined to maximize the number of semiconductor dies that may be fabricated on a wafer while at the same time optimizing the aspect ratio of the semiconductor die and/or contact shape to provide robust manufacture.

The examples described above discuss forming jumpers 2610 between semiconductor die 310 or 2710 and conductive traces 320; however, in other embodiments jumpers 2610 and conductive traces 320 are formed in one step. In these embodiments the process is similar to that described above, however, conductive traces 320 are not formed at the point in manufacture shown in FIG. 31. Instead, in these embodiments, semiconductor dies 310 or 2710 are connected in one step directly to each other. FIG. 31 shows a plan-view schematic of this embodiment prior to connection, in which semiconductor dies 310 are formed in an array. In this example semiconductor dies 310 are partially embedded in light-conversion material 720 in wells 1410, but this is not a limitation of the present invention. FIG. 32 shows a plan-view schematic after connection, where conductive traces 3210 directly connect one semiconductor die 310 to the next via jumpers 3210.

In some embodiments, semiconductor dies 310 and/or 2710 have a thickness in the range of about 75 μm to about 150 μm. In some embodiments, the semiconductor dies are thinned to more easily permit jumpers 2610 or 3210 to provide coverage over the sidewall step of the semiconductor dies. In some embodiments semiconductor dies 310 or 2710 have sloped sidewalls to aid in providing coverage over the sidewall step of the semiconductor dies. In some embodiments semiconductor dies 310 or 2710 have a thickness in the range of about 2 μm to about 15 μm. In some embodiments semiconductor dies 310 or 2710 have a thickness about the same as the thickness of jumper 2610 or conductive trace 320 or 3210.

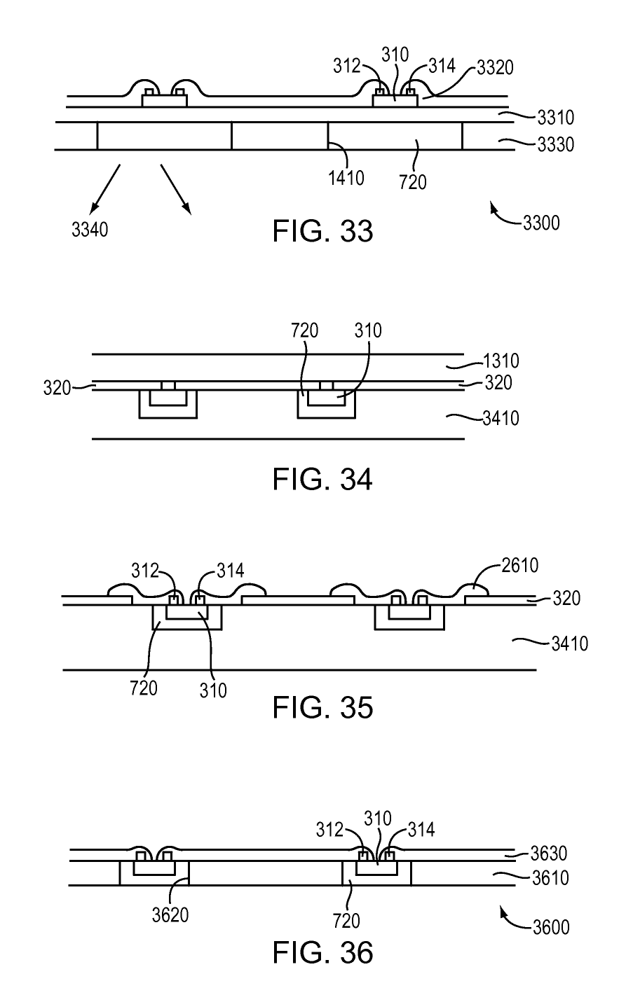

FIG. 33 depicts a lighting system 3300 in accordance with various embodiments of the invention that includes semiconductor dies 310 formed over a transparent substrate 3310. Semiconductor dies 310 may be electrically coupled using a variety of techniques, for example any of the methods previously described, e.g., the methods described in relation to FIGS. 25-32. System 3300 further includes wells 1410 in which light-conversion material 720 may be formed. Wells 1410 may be formed in a second substrate 3330, or in a portion of transparent substrate 3310. In some embodiments, second substrate 3330 is transparent, translucent or opaque to a wavelength of light emitted by semiconductor dies 310 and/or light-conversion material 720. Transparent substrate 3310 may be transparent to a wavelength of light emitted by semiconductor dies 310 and/or light-conversion material 720. In system 3300, light is emitted from semiconductor dies 310, partially absorbed by light-conversion material 720, and the resulting sum of light emitted by light-conversion material 720 and semiconductor dies 310 is emitted generally in direction 3340. In one embodiment system 3300 is optically coupled with an array of optical elements, as discussed above. Wells 1410 may be partially or completely filled with light-conversion material 720. As discussed above, light-conversion material 720 may include one or a plurality of materials. In some embodiments, all or portions of the walls of wells 1410 may be reflective to (or covered with a material reflective to) a wavelength of light emitted by semiconductor die 310 and/or light-conversion material 720.

It should be noted that while optical substrates have been described above as including optical elements, in other embodiments an optical substrate does not include optical elements. For example, FIGS. 34 and 35 show the structures of FIGS. 13 and 26B with optical substrate 610 replaced by substrate 3410. In some embodiments substrate 3410 includes materials discussed in relation to optical substrate 610. In some embodiments substrate 3410 includes materials discussed in relation to substrates 350, 710, and/or 1310. In some embodiments substrate 3410 includes features or materials that scatter or diffuse light emitted from light emitter 310 and/or light-conversion material 720. In some embodiments containment features as discussed in reference to FIGS. 8 and 9 are incorporated into structures shown in other figures. In some embodiments caps, as discussed in reference to FIG. 10, are incorporated into structures shown in other figures.

FIG. 36 depicts a lighting system 3600 in accordance with another embodiment of the present invention. System 3600 includes substrate 3610 having holes 3620 in which light-conversion material 720 is disposed. Semiconductor dies 310 are partially or fully immersed in light-conversion material 720 and electrical couplings to contacts 312, 314 of semiconductor dies 310 are formed using conductive traces 3630. In system 3600, light from semiconductor dies 310 and light-conversion material 720 mainly exits in the direction opposite the side of substrate 3610 over which conductive traces 3630 are formed. Optionally, an optical substrate including optical elements may be formed over the light-emitting side of system 3600 shown in FIG. 36. In some embodiments, all or portions of the walls of holes 3620 may be reflective to (or covered with a material reflective to) a wavelength of light emitted by semiconductor die 310 and/or light-conversion material 720. Optionally, a material reflective to a wavelength of light emitted by semiconductor dies 310 and/or light-conversion material 720 may be formed over all or portions of conductive traces 3630, semiconductor dies 310, contacts 312, 314 and/or substrate 3610.

The manufacture of system 3600 shown in FIG. 36 may start with the structure shown in FIG. 22. In FIG. 22, semiconductor dies 310 are temporarily attached, contact side down, to temporary substrate 2210. In one embodiment, semiconductor dies 310 are temporarily attached to substrate 2210 by an adhesive (not shown in FIG. 22). The adhesive may cover all of the surface of temporary substrate 2210, or only a portion of temporary substrate 2210 in the region of semiconductor dies 310. Semiconductor dies 310 are adhered to temporary substrate 2210 with the side of light-emitting element 310 having contacts 312, 314 proximate to temporary substrate 2210.

Temporary substrate 2210 may include any of a variety of materials, both rigid and flexible. For example temporary substrate 2210 may include metal, glass, plastic, ceramic or the like. In one embodiment temporary substrate 2210 includes or consists essentially of a semicrystalline or amorphous material, e.g., polyethylene naphthalate (PEN), polyethylene terephthalate (PET), polycarbonate, polyethersulfone, polyester, polyimide, polyethylene, and/or paper. Temporary substrate 2210 may include multiple layers and/or be flexible.

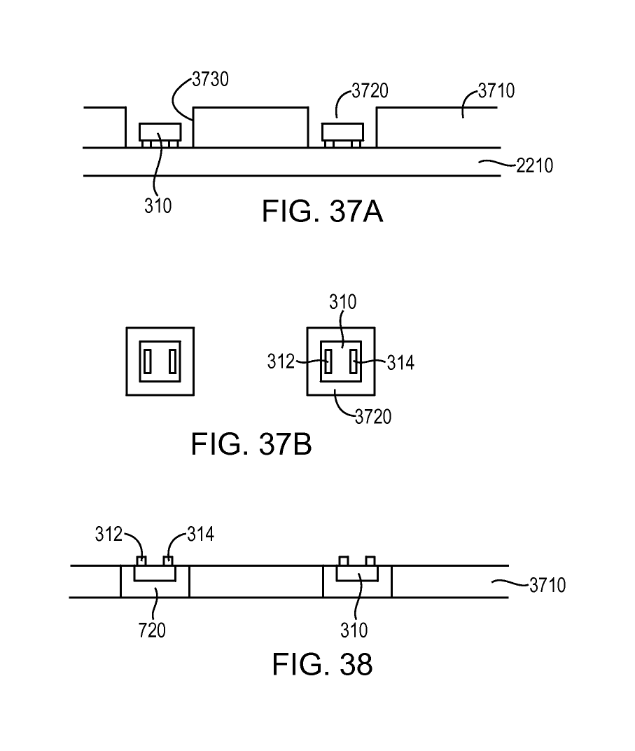

FIGS. 37A and 37B depict the structure of FIG. 22 at a later stage of manufacture; FIG. 37A is a cross-sectional view and FIG. 37B is a plan view. As shown, a layer 3710 has been formed over temporary substrate 2210. Layer 3710 includes a plurality of through-holes corresponding to the position of semiconductor dies 310 on temporary substrate 2210. After formation of layer 3710, the structure includes semiconductor dies 310 in wells 3720 formed in layer 3710. Layer 3710 may include any of the materials discussed in the previous paragraphs with respect to optical substrate 610 or other substrates. Through holes that include wells 3720 may be formed by a variety of techniques, for example laser cutting, punching, water jet cutting and the like.

FIGS. 37A and 37B depict wells 3720 having sidewalls 3730 perpendicular to the surface of temporary substrate 2210 but this is not a limitation of the present invention and in other embodiments sidewalls 3730 of openings 3720 are not substantially perpendicular to the surface of temporary substrate 2210 (as shown in FIG. 3a), but are sloped or otherwise shaped and/or patterned, for example to facilitate the out-coupling of light from the semiconductor dies 310 and/or out-coupling of light from light-conversion material 720 (see below). Sidewalls 3730 of openings 3720 may even be reflective to a wavelength of light emitted by light-emitting element 310 and/or light-conversion material 720. FIG. 37B shows wells 3720 having a square opening, however this is not a limitation of the present invention and in other embodiments wells 3720 may have any shape appropriate to the application, e.g., round, rectangular, hexagonal shape or any arbitrary shape. Different wells 3720 on the same layer 3710 may, in fact, have different shapes.

Wells 3720 may then be filled or partially filled with light-conversion material 720 and temporary substrate 2210 removed, as shown in FIG. 38, leaving contacts 312, 314 of semiconductor dies 310 exposed. In some embodiments portions of light-conversion material 720 are removed to expose contacts 312, 314. If an adhesive was used to temporarily hold semiconductor dies 310 to temporary substrate 2210, the adhesive may be optionally removed, at least in the regions of contacts 312, 314 of semiconductor dies 310. The adhesive may be removed by a variety of means, including for example peeling, etching, dissolving, grinding, plasma treatments or the like. Temporary substrate 2210 may be removed, for example by peeling, etching, dissolving, grinding or the like. In some embodiments temporary substrate 2210 may be a releasable substrate, where the adhesive or tack level may be modified, for example reduced by some means. In one embodiment release may be achieved by heating temporary substrate 2210. In one embodiment release may be achieved by exposure of substrate 2210 to radiation, for example UV radiation.

Light-conversion material 720 may include a material transparent to a wavelength of light generated by light-emitting element 310 or may include a light-conversion material or both. A light-conversion material 720 may include a phosphor including or consisting essentially of, e.g., one or more silicates, nitrides, quantum dots, or other light-conversion materials, and may be suspended in an optically transparent binder (e.g., silicone or epoxy). Semiconductor dies 310 for use with one or more phosphors may emit substantially blue or ultraviolet light, and the use of the phosphor(s) may result in aggregate light that is substantially white, and which may have a correlated color temperature (CCT) ranging from approximately 2000 K to approximately 7000 K.

Examples of such dies are those including GaN, InN, AlN and various alloys of these binary compounds. Light-conversion material 720 may include a homogeneous or substantially homogeneous material or mixture, or a non-homogeneous material, or may include layers or other divisions of light-conversion and/or transparent materials. For example, in one embodiment a transparent material may first cover light-emitting element 310, and this may then be covered or partially covered by a light-conversion material.

In the next stage of manufacture semiconductor dies 310 may be electrically coupled together through conductive traces 3630, as shown in FIG. 36. Conductive traces 3630 preferably include or consist essentially of one or more conductive materials, e.g., a metal or metal alloy, carbon, graphene, etc. Conductive traces 3630 may be formed via conventional deposition, photolithography, and etching processes, plating processes, tape, wire, or may be formed using a variety of printing processes. For example, conductive traces 3630 may be formed via screen printing, flexographic printing, ink jet printing, and/or gravure printing. Conductive traces 3630 may include or consist essentially of a conductive ink, which may include one or more elements such as silver, gold, aluminum, chromium, copper, and/or carbon, graphene. The thickness of conductive traces 3630 may be in the range of about 25 nm to about 100 μm. While the thickness of one or more of the conductive traces 3630 may vary, the thickness is generally substantially uniform along the length of the conductive trace to simplify processing. However this is not a limitation of the present invention and in other embodiments the conductive trace thickness or material varies.

In some embodiments the semiconductor dies and/or light-conversion materials are different within one lightsheet. For example, a lightsheet may include a plurality of semiconductor dies, each emitting at substantially the same wavelengths, but different composition, concentration or thickness light-conversion materials may be associated with different semiconductor dies. In one embodiment a yellow-emitting phosphor and a red-emitting phosphor may be formed in different groups of wells to provide improved color temperature and CRI and uniformity of color temperature and CRI. In one embodiment a lightsheet includes a plurality of semiconductor dies that may be divided into groups, and each group may emit light of a different wavelength. For example, in one embodiment a first group of semiconductor dies emits in the red wavelength range and a second group of semiconductor dies emits in the blue wavelength range. In one embodiment, a first group of semiconductor dies is optically coupled with a light-conversion material while a second group of semiconductor dies is not optically coupled with a light-conversion material.

In one embodiment a lightsheet includes a plurality of two or more different types of semiconductor dies, for example emitting at two or more different wavelengths. In one embodiment such a lightsheet includes the two or more different types of semiconductor die associated with or embedded in a single type of light-conversion material. In one version of this embodiment, the two or more different semiconductor dies are positioned near or next to each other and are associated with or embedded in the same portion of the light-conversion material.

In one embodiment a lightsheet includes two or more semiconductor dies associated with or embedded in two or more different types of light-conversion material. In one embodiment such a lightsheet includes the two or more semiconductor dies, where at least one of the two or more semiconductor dies is not associated with or embedded in a light-conversion material and the remaining two or more semiconductor dies are associated with or embedded in one or more types of light-conversion material.

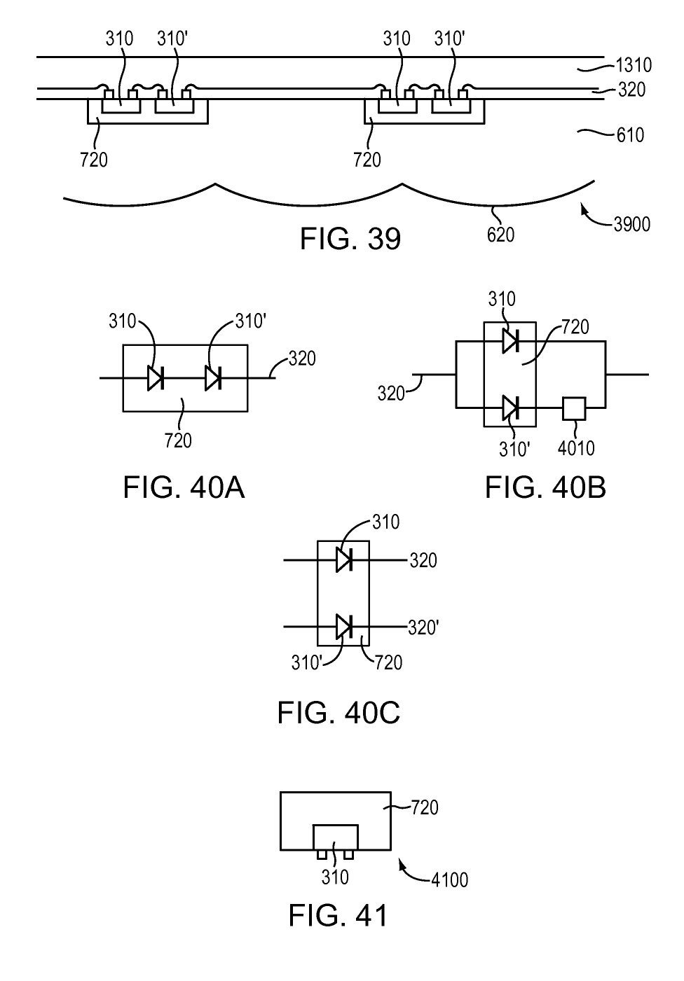

FIG. 39 depicts a lighting system 3900, similar to that shown in FIG. 13, featuring semiconductor die 310 and semiconductor die 310′. Semiconductor dies 310 and 310′ are covered or partially covered by the same portion of light-conversion material 720. In one embodiment semiconductor die 310 may emit in the blue wavelength range, for example between about 400 nm to about 500 nm and semiconductor die 310′ may emit in the red wavelength range, for example between about 550 nm to about 700 nm, preferably between about 600 nm to about 670 nm. Such an arrangement may be used to achieve a higher color rendering index by the addition of semiconductor die 310′ emitting in the red wavelength range. In such an arrangement semiconductor dies 310 and 310′ may be operated at the same or different current levels to achieve the desired optical characteristics. In some embodiments the current to semiconductor dies 310 and/or 310′ may be passively or actively controlled to be the same or different in each semiconductor die. In some embodiments each portion of light-conversion material 720 is associated with both semiconductor dies 310 and 310′, while in other embodiments different portions of light-conversion material 720 (e.g., in other wells on the substrate) may have only one of semiconductor die 310 or 310′.

In some embodiments semiconductor die 310′ may have a forward voltage that is different from that of semiconductor die 310 and in these cases it may be desirable to independently control the current in semiconductor dies 310 and 310′. For example, in the case of semiconductor die 310 including or consisting essentially of a GaN-based LEE emitting in the blue wavelength regime, the forward voltage may be in the range of about 2.5 V to about 3.5 V. In the case of semiconductor die 310′ including or consisting essentially of an InGaAlP-based LEE emitting in the red wavelength regime, the forward voltage may be in the range of about 1.8 V to about 2.8 V.

FIGS. 40A, 40B, and 40C schematically depict several different drive schemes for paired semiconductor dies. In FIG. 40A, semiconductor dies 310 and 310′ are driven in series. In FIG. 40B semiconductor dies 310 and 310′ are driven in parallel. In some embodiments of FIG. 40B, one or both of the portions of the circuit that contain semiconductor dies 310 or 310′ may also include a control element 4010, which may include or consist essentially of one or more active or passive devices, circuit elements, or circuits. In one embodiment control element 4010 includes a resistor having a resistance selected to achieve the desired current level through semiconductor die 310′.

In one embodiment control element 4010 includes a second diode and in some examples the second diode may be the same as the semiconductor die it is in series with. Where control element 4010 includes a diode, in some embodiments the voltage drop across control element 4010 and semiconductor die 310′ may be selected to be the same or substantially the same as the voltage drop across the circuit elements in the other circuit leg (e.g., semiconductor die 310). FIG. 40C shows an example of an embodiment where semiconductor die 310 and 310′ are driven independently. FIGS. 40A-40C show two semiconductor dies 310; however, this is not a limitation of the present invention and in other embodiments more than two semiconductor dies 310 may be utilized.

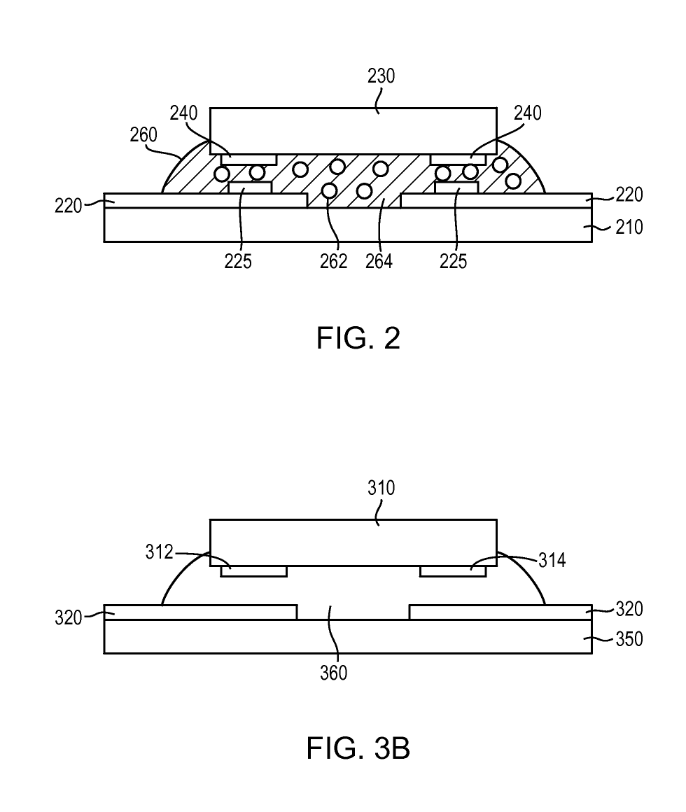

In yet another set of embodiments semiconductor die 310 and/or semiconductor die 310′ is associated with or covered or partially covered by light-conversion material 720 before attachment to a substrate, for example substrate 210 as shown in FIG. 2, substrate 350 as shown in FIGS. 3A and 3B, optical substrate 610 as shown in FIGS. 6A and 6B, substrate 710 in FIG. 7, substrate 1310 in FIG. 17, substrate 2210 in FIG. 22, substrate 3310 in FIG. 33, substrate 2410 in FIG. 34, or substrate 3610 in FIG. 36 or the like. FIG. 41 shows an example of a structure 4100 that includes a semiconductor die 310 associated with light-conversion material 720 before attachment to a substrate. Structure 4100 may also be referred to as a white die. In some embodiments white die 4100 may be formed by forming light-conversion material 720 over and/or around multiple semiconductor dies 310 formed on a temporary substrate and then separating this structure into individual white dies and removing them from the temporary substrate, resulting in the structure shown in FIG. 41 and as described in U.S. Provisional Patent Application No. 61/589,908, the entirety of which is hereby incorporated by reference. For example, in one embodiment, the manufacture of white die 4100 starts with the structure shown in FIG. 22, and substrate 2210 is a temporary substrate. A light-conversion material, for example one including a binder and one or more phosphors, is formed over semiconductor die 310 and temporary substrate 2210. The light-conversion material may optionally be cured and then separated into individual white dies, as shown in FIG. 41, before or after removal from temporary substrate 2210.

FIG. 41 shows one semiconductor die 310 associated with light-conversion material 720 but this is not a limitation of the present invention and in other embodiments a plurality of semiconductor dies 310 may be associated with light-conversion material 720. FIG. 41 shows light-conversion material 720 having a square or rectangular shape; however, this is not a limitation of the present invention and in other embodiments light-conversion material 720 has a hemispherical or substantially hemispherical shape, a parabolic or substantially parabolic shape, or any shape. FIG. 41 shows substantially the same thickness of light-conversion material 720 over the top and side walls of semiconductor die 310; however, this is not a limitation of the present invention and in other embodiments, the thickness of light-conversion material 720 varies over different portions of semiconductor die 310.

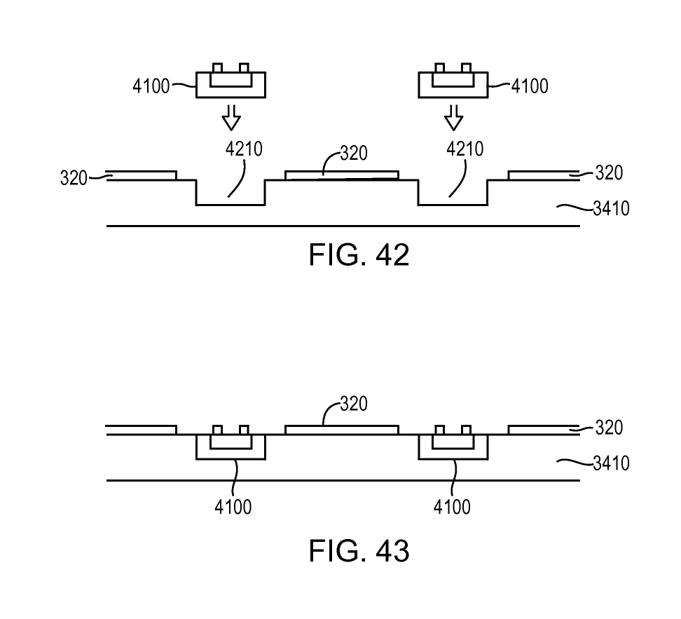

White die 4100 may be used to produce embodiments of this invention, instead of forming light-conversion material 720 over semiconductor die 310 after attachment of semiconductor die 310 to a substrate. For example the structure of FIGS. 6A, 6B, 7, 10, 13, 19, 21, 26B, 35, 36, 38 or the like may be manufactured using one or more white dies 4100. As an example, FIG. 42 shows the structure of FIG. 35 at an early stage of manufacture. FIG. 42 shows substrate 3410 including wells or holes 4210 into which white dies 4100 may be placed. FIG. 43 shows white dies 4100 after insertion or partial insertion or placement in wells 4210. White dies 4100 may be placed in wells 4210 by a variety of means, for example using pick-and-place tools. In some embodiments white dies 4100 may be press-fit into wells 4210. In some embodiments, well 4210 may have substantially the same shape as white die 4100; however, this is not a limitation of the present invention and in other embodiments well 4210 may have any shape. In some embodiments, well 4210 may have a size or volume similar to that of white die 4100; however, this is not a limitation of the present invention and in other embodiments well 4210 may have any size or volume. In some embodiments a white die 4100 may be adhered in a well 4210 using for example a glue, adhesive, tape or the like. In some embodiments there is a space between white die 4100 and well 4210, and this space may be partially or completely filled with a material that adheres white die 4100 to well 4210 or substrate 3410. For example, the space between white die 4100 and well 4210 may be partially or completely filled with a transparent encapsulating matrix material that not only adheres white die 4100 to well 4210 and/or substrate 3410, but that also aids in reducing TIR losses in white die 4100, for example by having an index of refraction of, e.g., at least about 1.3, and preferably above about 1.4. In one embodiment, the filler provides an index match but does not provide substantial adhesion of white die 4100 to well 4210. In one embodiment there is no filler in the space between white die 4100 and well 4210. In one embodiment white die 4100 is press-fit into well 4210. The structure of FIG. 35 may then be realized by formation of jumpers 2610, as described above in reference to FIG. 35. In another embodiment the process described above may be performed with a substrate having optical elements, such as that shown in FIG. 26B.

In general in the above discussion the arrays of semiconductor dies, light emitting elements, wells, optics and the like have been shown as square or rectangular arrays; however this is not a limitation of the present invention and in other embodiments these elements may be formed in other types of arrays, for example hexagonal, triangular or any arbitrary array. In some embodiments these elements may be grouped into different types of arrays on a single substrate.

In some embodiments, the LEEs of one or more lightsheets are of the same type. In some embodiments, the LEEs of one or more lightsheets may be different. In some embodiments, a single lightsheet may include multiple different types of LEEs. For example, different types of LEEs may include different sized LEEs or LEEs that have different electrical or optical characteristics, such as emission wavelength or spectral power density. In some embodiments, each string may include or consist essentially of multiple LEEs of the same type; however, this is not a limitation of the present invention and in other embodiments each string may include or consist essentially of more than one type of LEE, for example LEEs that emit light at different wavelengths or with different spectral power densities or have different sizes. In some embodiments, a lightsheet may feature multiple strings, where each string includes or consists essentially of multiple LEEs of the same type; however, this is not a limitation of the present invention and in other embodiments the lightsheet may include or consist essentially of multiple strings where each string may include or consist essentially of more than one type of LEE, for example LEE that emit light at different wavelengths or with different spectral power densities or have different sizes. The number of different types of LEEs is not a limitation of the present invention. In some embodiments, a lighting system includes or consists essentially of a plurality of lightsheets. The number of lightsheets and the number of different types of lightsheets within a lighting system is not a limitation of the present invention. In some embodiments, a lightsheet and/or lighting system may include a combination of bare-die LEEs and packaged LEEs.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1-53. (canceled)

54. A light-emitting device, comprising
an optical substrate comprising (i) a plurality of cavities in a first surface thereof and (i) a plurality of electrical traces disposed on the first surface thereof; and
a plurality of light-emitting elements each (i) at least partially inserted into one of the cavities in the optical substrate, (ii) electrically connected to at least two electrical traces on the optical substrate, and (iii) at least partially surrounded by a light-conversion material.

55. The light-emitting device of claim 54, further comprising a plurality of optical elements (i) disposed on a second surface of the optical substrate opposite the first surface and (ii) each substantially aligned with a cavity in the first surface.

56. A light-emitting device, comprising
an optical substrate;
a plurality of electrical traces disposed on a first surface of the optical substrate;
a plurality of light-emitting elements disposed over the first surface of the optical substrate, each light-emitting element being (i) electrically connected to at least two electrical traces on the first surface of the optical substrate, and (ii) at least partially surrounded by a light-conversion material; and
a reflective surface disposed over each light-emitting element.

57. The light-emitting device of claim 56, wherein the light-conversion material is disposed on the light-emitting element.

58. The light emitting device of claim 56, wherein the light-conversion material is disposed on the reflective surface.

59. The light-emitting device of claim 56, wherein the reflective surface has a substantially parabolic shape and the light-emitting element thereunder is disposed at a focal point thereof.

60. The light-emitting device of claim 56, further comprising a plurality of optical elements (i) disposed on a second surface of the optical substrate opposite the first surface and (ii) each substantially aligned with a light-emitting element.

61. The light-emitting device of claim 56, wherein each of the light-emitting elements comprises a bare-die light-emitting diode.

62. The light-emitting device of claim 61, wherein each bare-die light-emitting diode comprises one or more semiconductor materials selected from the group consisting of silicon, InAs, AlAs, GaAs, InP, AlP, GaP, InSb, GaSb, AlSb, GaN, AlN, InN, and mixtures and alloys thereof.

63. The light-emitting device of claim 56, wherein each of the light-emitting elements comprises a packaged light-emitting diode.

64. The light-emitting device of claim 63, wherein each packaged light-emitting diode comprises one or more semiconductor materials selected from the group consisting of silicon, InAs, AlAs, GaAs, InP, AlP, GaP, InSb, GaSb, AlSb, GaN, AlN, InN, and mixtures and alloys thereof.

65. The light-emitting device of claim 56, wherein each light-emitting element is electrically connected to at least two electrical traces by a conductive adhesive.

66. The light-emitting device of claim 65, wherein the conductive adhesive comprises an anisotropic conductive adhesive.

67. The light-emitting device of claim 56, wherein the light-conversion material comprises a phosphor and a binder.

68. The light-emitting device of claim 67, wherein the phosphor comprises at least one of lutetium aluminum garnet, yttrium aluminum garnet, a nitride-based phosphor, or a silicate-based phosphor.

69. The light-emitting device of claim 67, wherein the binder comprises at least one of silicone, polydimethylsiloxane, or epoxy.
